(19) United States
(12) Patent Application Publication
(10) Pub. No.: US 2007/0247906 A1
(43) Pub. Date: Oct. 25, 2007

(54) Fin type memory cell

(76) Inventors: Hiroshi Watanabe, Yokohama-shi (JP); Yoshifumi Nishi, Kawasaki-shi (JP); Atsuhiro Kinoshita, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/723,335

(22) Filed: Mar. 19, 2007

(30) Foreign Application Priority Data
Mar. 28, 2006 (JP) 2006-087783

(51) Int. Cl. G11C 16/04

(52) U.S. Cl. 365/185.14

(57) ABSTRACT

A Fin-type memory cell according to an example of the present invention includes a fin-shaped active area, a floating gate along a side surface of the fin-shaped active area, and two control gate electrodes arranged in a longitudinal direction of the fin-shaped active area, and sandwiching the floating gate.

### CROSS-REFERENCE TO RELATED APPLICATIONS

This application is based upon and claims the benefit of priority from prior Japanese Patent Application No. 2006-087783, filed Mar. 28, 2006, the entire contents of which are incorporated herein by reference.

### BACKGROUND OF THE INVENTION

1. Field of the Invention

The present invention relates to a Fin type memory cell to be formed in a fin-shaped active area.

2. Description of the Related Art

A system LSI realizing one system in one chip is a technique widely noticed while the electronic equipment is downsized. For example, in the system LSI mounted in an IC card, blocks such as a logic circuit and a nonvolatile semiconductor memory are mixed-mounted in one chip.

Here, there is one problem of consistency of processes between the logic circuit and the nonvolatile semiconductor memory. For example, a CMOS process for use in the logic circuit and a memory process for use in the nonvolatile semiconductor memory have many parts not compatible with each other which are mismatch of film formation method between a gate insulating film of a CMOS circuit and a tunnel oxide film of a memory cell, or the like. Thus, there is the problem that processes become complicated.

In consideration of such an actual situation, as for the technique concerning a CMOS-memory mixed mounting process, until now, some effective techniques such as the technique disclosed in U.S. Pat. No. 6,853,583 have been proposed.

By the way, recently, a Fin-FET as the major candidate of post-MOSFET is widely noticed. The Fin-FET is the MOSFET formed in an active area with a fin shape, and for example, application of the Fin-FET to the logic circuit in a system LSI is investigated.

In this case, consider consistency of the process between the logic circuit and the nonvolatile semiconductor memory. If the nonvolatile semiconductor memory in the system LSI is also constituted with the Fin-type memory cell, a manufacturing cost of the system LSI decreases effectively due to simplification of the process.

Thereupon, for example, JP-A 2005-243709 (KOKAI) has proposed a nonvolatile semiconductor memory composed of a Fin-type memory cell. However, in the technique proposed here, like the memory cell of the current nonvolatile semiconductor memory, the Fin-type memory cell has a stack gate structure. As a consequence, it is not possible to achieve rapid reduction of the manufacturing cost due to simplification of the process.

### BRIEF SUMMARY OF THE INVENTION

(1) Fin Type Memory Cell

A fin type memory cell according to an aspect of the invention comprises a fin-shaped active area, a floating gate along a side surface of the active area, and two control gate electrodes arranged in a longitudinal direction of the active area to the floating gate, the control gate electrodes sandwiching the floating gate.

A fin type memory cell according to an aspect of the invention comprises a fin-shaped active area, a first floating gate arranged along a first side surface of the active area, a second floating gate arranged along a second side surface opposite to the first side surface of the active area, first and second control gate electrodes arranged in a longitudinal direction of the active area to the first floating gate, the first and second control gate electrodes sandwiching the first floating gate, and third and fourth control gate electrodes arranged in a longitudinal direction of the active area to the second floating gate, the third and fourth control gate electrodes sandwiching the second floating gate.

(2) Fin-NAND Type Flash Memory

A Fin-NAND type flash memory according to an aspect of the invention comprises a fin-shaped active area, floating gates and control gate electrodes which are alternately arranged along a side surface of the active area in its longitudinal direction, and a Fin type memory cell composed of one of the floating gates and the two control gate electrodes arranged at positions mutually adjacent to the one electrode.

A Fin-NAND type flash memory (2-level) according to an aspect of the invention comprises a fin-shaped active area, first floating gates and first control gate electrodes which are alternately arranged along a first side surface of the active area in its longitudinal direction, second floating gates and second control gate electrodes which are alternately arranged along a second side surface opposite to the first side surface of the active area in its longitudinal direction, and a Fin-type memory cell composed of one of the first floating gates and the two first control gate electrodes arranged at positions mutually adjacent to the one first floating gate, and one of the second floating gates and the two second control gate electrodes arranged at positions mutually adjacent to the one second floating gate.

A Fin-NAND type flash memory (multi-level) according to an aspect of the invention comprises a fin-shaped active area, first floating gates and first control gate electrodes which are alternately arranged along a first side surface of the active area in its longitudinal direction, second floating gates and second control gate electrodes which are alternately arranged along a second side surface opposite to the first side surface of the active area in its longitudinal direction, a first Fin-type memory cell composed of one of the first floating gates and the two first control gate electrodes arranged at positions mutually adjacent to the one first floating gate, and a second Fin-type memory cell composed of one of the second floating gates and the two second control gate electrodes arranged at positions mutually adjacent to the one second floating gate.

(3) Semiconductor Memory (Oblique Word Line)

A semiconductor memory according to an aspect of the invention comprises a memory cell array composed of memory cells arranged in first and second directions orthogonal to each other in an array shape, and a word line connected to a gate of the memory cells, the word line extending in a third direction between the first and the second directions, wherein the memory cells connected in common to one of the word lines are arranged in the third direction.

### BRIEF DESCRIPTION OF THE SEVERAL VIEWS OF THE DRAWING

FIG. 1 is a plan view showing a basic structure of a Fin-type memory cell of the present invention;

FIG. 2 is a perspective view showing the basic structure of the Fin-type memory cell of the invention;

FIG. 3 is a view showing a capacitive coupling generated in the Fin-type memory cell of the invention;

FIG. 4 is a view showing a potential relation between a floating gate and a control gate electrode;

FIG. 5 is a view showing an example of a size of the Fin-type memory cell of the invention;

FIG. 6 is a block diagram showing a Fin-NAND type flash memory of the invention;

FIG. 7 is a circuit diagram showing a configuration of a memory cell array;

FIG. 8 is a plan view showing a first example of a layout of the invention;

FIG. 9 is a plan view showing a second example of the layout of the invention;

FIG. 10 is a plan view showing a third example of the layout of the invention;

FIGS. 11A and 11B are views showing a structure example in the case where the layout of FIG. 10 is three-dimensionally formed;

FIG. 12 is a plan view showing a fourth example of the layout of the invention;

FIG. 13 is a view showing a structure example in the case where the layout of FIG. 12 is three-dimensionally formed;

FIG. 14 is a view showing a structure example in the case where the layout of FIG. 12 is three-dimensionally formed;

FIG. 15 is a view showing a structure example in the case where the layout of FIG. 12 is three-dimensionally formed;

FIG. 16 is a view showing a structure example in the case where the layout of FIG. 12 is three-dimensionally formed;

FIG. 17 is a plan view showing a fifth example of the layout of the invention;

FIG. 18 is a plan view showing a sixth example of the layout of the invention;

FIG. 19 is a plan view showing a seventh example of the layout of the invention;

FIG. 20 is a view showing a structure example in the case where the layout of FIG. 19 is three-dimensionally formed;

FIG. 21 is a view showing a structure example in the case where the layout of FIG. 19 is three-dimensionally formed;

FIG. 22 is a view showing a structure example in the case where the layout of FIG. 19 is three-dimensionally formed;

FIG. 23 is a view showing a structure example in the case where the layout of FIG. 19 is three-dimensionally formed;

FIG. 24 is a view showing a threshold value distribution of the Fin-type memory cell of the invention;

FIG. 25 is a view showing a potential relation of a cell unit at the time of write operation;

FIG. 26 is a view showing a potential relation of the cell unit at the time of read operation;

FIG. 27 is a view showing a potential relation of the cell unit at the time of erase operation;

FIG. 28 is a plan view showing a basic structure of a multi-level Fin-type memory cell;

FIG. 29 is a perspective view showing a basic structure of a multi-level Fin-type memory cell;

FIG. 30 is a plan view showing a first example of a layout of the multi-level Fin-type memory cell;

FIG. 31 is a plan view showing a second example of the layout of the multi-level Fin-type memory cell;

FIG. 32 is a plan view showing a third example of the layout of the multi-level Fin-type memory cell;

FIG. 33 is a plan view showing a fourth example of the layout of the multi-level Fin-type memory cell;

FIG. 34 is a view showing an example of a word line layout;

FIG. 35 is a view showing an example of a word line layout;

FIG. 36 is a view showing a structure example in the case where the layout of FIG. 33 is three-dimensionally formed;

FIG. 37 is a view showing a structure example in the case where the layout of FIG. 33 is three-dimensionally formed;

FIG. 38 is a view showing a structure example in the case where the layout of FIG. 33 is three-dimensionally formed;

FIG. 39 is a view showing a structure example in the case where the layout of FIG. 33 is three-dimensionally formed;

FIG. 40 is a view showing a threshold value distribution of the multi-level Fin-type memory cell;

FIG. 41 is a view showing a potential relation of the cell unit at the time of “10” write operation;

FIG. 42 is a view showing a potential relation of the cell unit at the time of “01” write operation;

FIG. 43 is a view showing a potential relation of the cell unit at the time of “11” write operation;

FIG. 44 is a view showing a potential relation of the cell unit at the time of read operation;

FIG. 45 is a view showing an example of a system LSI;

FIG. 46A is a circuit diagram showing a configuration of 3-Tr Fin-NAND; and

FIG. 46B is a circuit diagram showing a configuration of 2-Tr Fin.

### DETAILED DESCRIPTION OF THE INVENTION

A fin type memory cell of an aspect of the present invention will be described below in detail with reference to the accompanying drawings.

### 1. Outline

In an example of the present invention, the following structure is proposed as a Fin-type memory cell with a suitable structure for mixed mounting between a logic circuit composed of a Fin-FET and the Fin-type memory cell. The structure is composed of a floating gate along a side surface of a fin-shaped active area and two control gate electrodes arranged in a longitudinal direction of the active area to the floating gate, the two control gate electrodes sandwiching the floating gate.

According to such a structure, the Fin-type memory cell does not have a stack gate structure. That is, like the gate electrode of the Fin-FET, it is possible to form the floating gate and the control gate electrode by one time of accumulation step and one time of lithography step, and thus, it is possible to achieve rapid reduction of manufacturing cost due to simplification of the manufacturing process.

Further, the floating gate is sandwiched between two control gate electrodes, so that a potential of the floating gate is controlled by these two control gate electrodes. For this reason, it becomes possible to control the potential of the floating gate accurately, and consequently, operation stability of the Fin-type memory cell is improved.

Moreover, as a result that it is possible to accurately control the potential of the floating gate, variation of a threshold voltage of the Fin-type memory cell decreases, and the shape of a threshold distribution of data to be stored in the Fin-type memory cell can be made sharp. Therefore, it is possible to realize lowering of the power supply voltage, and as a result, it is possible to achieve realizing low power consumption and prevention of break of the Fin-FET constituting the peripheral circuit. Further, since it is possible to adopt a large signal ratio of plural items of data stored in the Fin-type memory cell, read margin used in the case of judging a value of the read data becomes large.

### 2. Embodiments

Next, there will be described some embodiments considered as the most preferable case.

### (1) Basic Structure

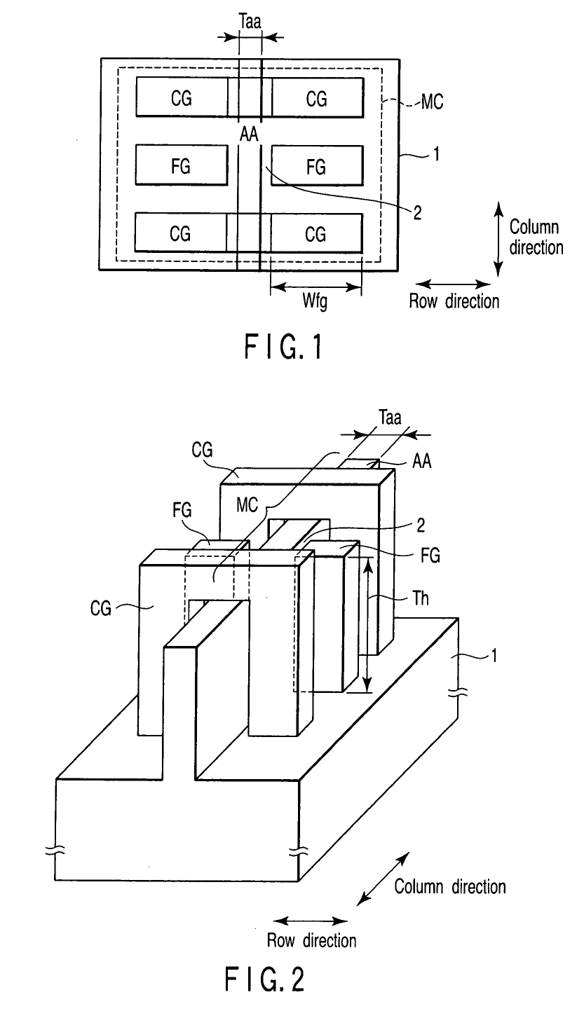

FIGS. 1 and 2 show a basic structure of a Fin-type memory cell according to an embodiment of the invention.

The Fin-type memory cell MC is formed in a fin-shaped active area AA on a semiconductor substrate 1. A longitudinal direction of the active area AA is a column direction, and a thickness of the active area AA in a row direction is set to Taa.

A floating gate FG is arranged along a side surface of the active area AA. There is arranged a tunnel insulating film 2 made of, for example, silicon oxide between the floating gate FG and the active area AA.

Two control gate electrodes CG sandwiching the floating gate FG therebetween are arranged in the longitudinal direction of the active area AA to the floating gate FG.

In this embodiment, one Fin-type memory cell MC is composed of floating gates FG arranged at both side surfaces of the active area AA, and two bridge-shaped control gate electrodes CG mounted by straddling the active area AA in the row direction.

Since the same data is stored in the floating gates FG respectively arranged at the both side surfaces of the active area AA, like the control gate electrode CG, bridge shape may be adopted by connecting the both.

However, if the floating gates FG are shaped in a bridge, leakage currents due to centralization of an electric field may be generated in some cases at an upper corner part of the active area AA. For this reason, it is preferable that the floating gates FG at the both side surfaces of the active area AA are separated from each other.

Although, in the case of the embodiment, the floating gates FG and the control gate electrodes CG are respectively arranged at the both side surfaces of the active area AA, these electrodes may be arranged at only one side surface of the active area AA.

As for the control gate electrode CG, like the floating gate FG, each control gate electrode CG may be arranged at one side surface of the active area AA independently without adopting the bridge shape. In this case, however, a word line for connecting them with each other is arranged on the control gate electrode CG.

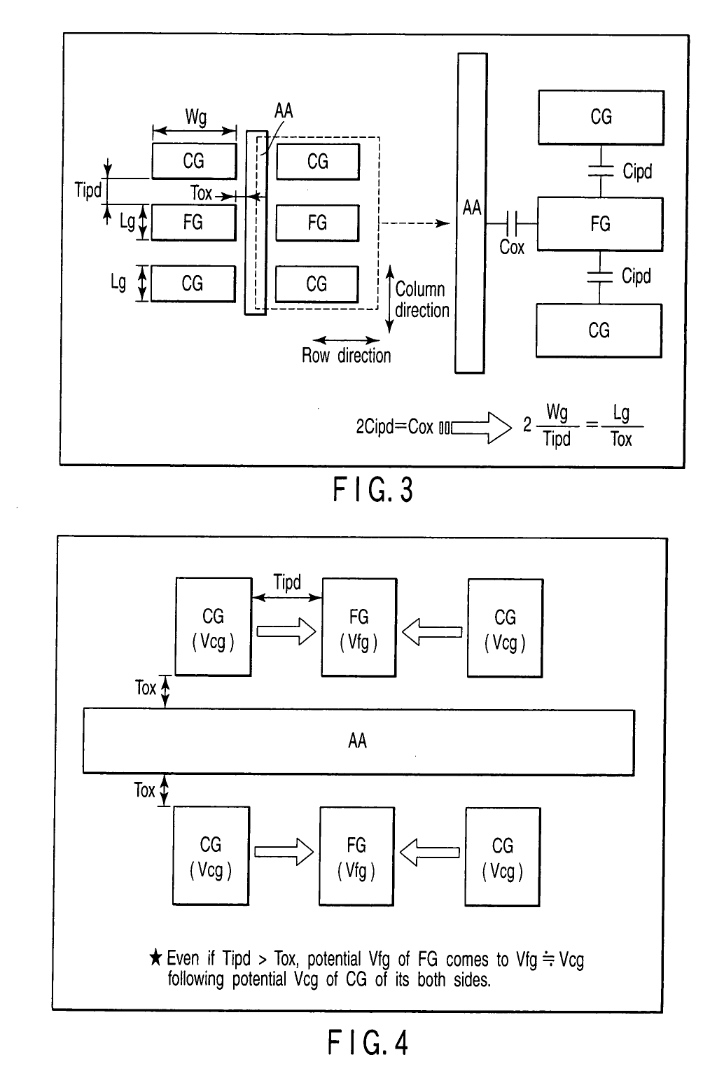

FIG. 3 shows a capacitive coupling generated on the Fin-type memory cell.

One of characteristics of the Fin-type memory cell according to the embodiment of the invention is that two control gate electrodes CG are arranged in such a shape that the floating gate FG is sandwiched therebetween, and the potential of the floating gate FG is made to control with these two control gate electrodes CG.

Accordingly, it becomes possible to control the potential of the floating gate FG accurately, so that operation stability of the Fin-type memory cell is improved.

Here, capacitance Cox which is generated between the active area AA and the floating gate FG is expressed by εox(Lg×Th)/Tox, and capacitance 2Cipd which is generated between the floating gate FG and the control gate electrode CG is expressed by 2εipd(Wg×Th)/Tipd.

Provided that Lg is a width of the floating gate FG in a column direction; Th is a height of the floating gate FG (refer to FIG. 2); Tox is a thickness of the tunnel insulating film; Wg is a width of the floating gate FG in the row direction; Tipd is a thickness of an insulating film between the floating gate FG and the control gate electrode CG, that is, a thickness of an inter poly-dielectric; εox is a specific dielectric constant of the tunnel insulating film; and εipd is a specific dielectric constant of the inter poly-dielectric.

For ease of explanation, assume that the specific dielectric constant εox of the tunnel insulating film is equal to the specific dielectric constant sipd of the inter poly-dielectric, and a capacitive coupling ratio between a capacitance generated between the active area AA and the floating gate FG and a capacitance between the floating gate FG and the control gate electrode CG is 0.5. In this case, relation of 2Wg/Tipd=Lg/Tox is established.

Off course, it is permissible that the capacitance coupling ratio is larger than 0.5, that is, 2Wg/Tipd>Lg/Tox.

FIG. 4 shows a relation between a potential Vfg of the floating gate FG and a potential Vcg of the control gate electrode CG.

If the potential Vfg of the floating gate FG is controlled by two control gate electrodes CG, the potential Vfg of the floating gate FG can be brought near the potential Vcg of the control gate electrode CG as compared with a conventional case in which the potential of the floating gate FG is controlled by one control gate electrode FG.

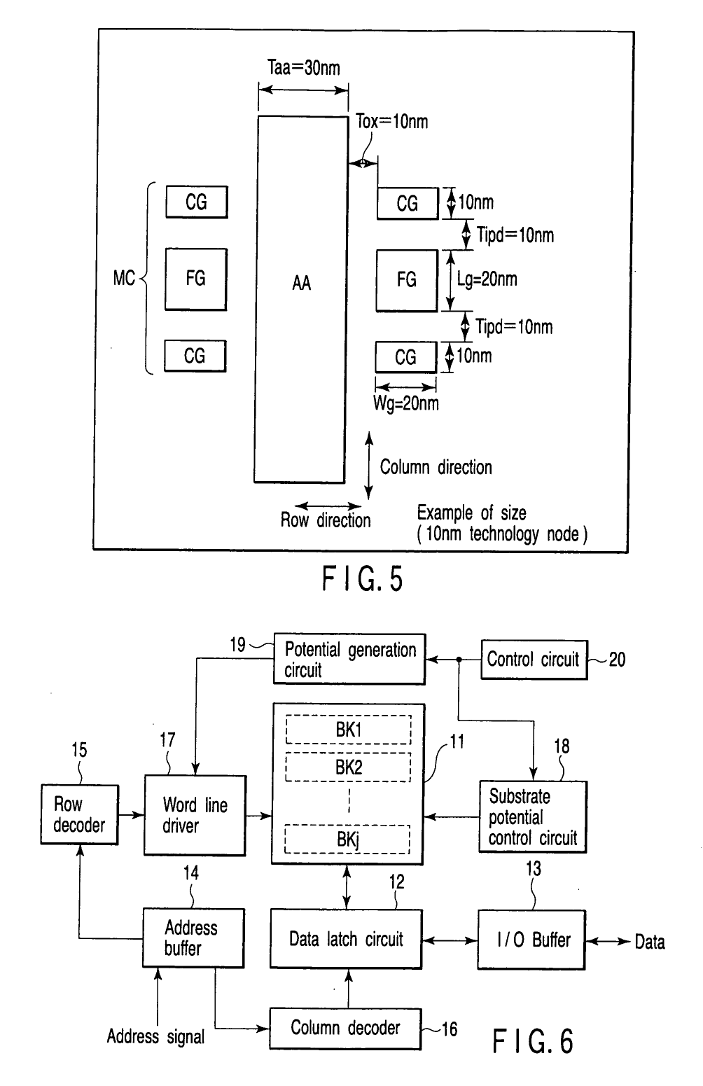

FIG. 5 shows an example of the size of the Fin-type memory cell.

Assuming a technology node to become basis of size determination is 10 nm, it is possible to set the width Taa of the active area AA to 30 nm, a plane size Wg×Lg of the floating gate FG to 20 nm×20 nm, and the thickness Tox of the tunnel insulating film and the thickness Tipd of the inter poly-dielectric to 10 nm each.

As for the plane size of the control gate electrode CG, it is possible to achieve reduction of the cell size by setting the width in the column direction to 10 nm.

Note that a memory cell size can be changed freely by considering the technology node or memory capacity of a nonvolatile semiconductor memory necessary for the system LSI.

### (2) Fin-NAND Type Flash Memory

The Fin-type memory cell according to the embodiment of the invention can be applied to various nonvolatile semiconductor memories without depending on the type of the memory cell array, such as, for example, NAND type, NOR type, 2-Tr type or 3-Tr NAND type. However, hereinafter, as a representative example, there will be described a case in which the Fin-type memory cell according to the embodiment of the invention is applied to a NAND type flash memory.

### A. Whole View

FIG. 6 shows a whole view of a Fin-NAND type flash memory.

A block configuration of the Fin-NAND type flash memory does not differ from that of a general NAND type flash memory at all.

A memory cell array 11 is composed of a plurality of blocks BK1, BK2, . . . BKj. Each of the plurality of blocks BK1, BK2, . . . BKj has a plurality of cell units, and each of the cell units is composed of a NAND string constituted by a plurality of memory cells connected in series and two select gate transistors connected to both ends thereof one by one.

A data latch circuit 12 has a function to latch data temporarily at the time of read/write, and is constituted by, for example, a flip-flop circuit. An input/output (I/O) buffer 13 functions as an interface circuit for data, and an address buffer 14 functions as an interface circuit for an address signal.

A row decoder 15 and a column decoder 16 select the memory cell inside the memory cell array 11 based on an address signal. A word line driver 17 drives a selected word line inside a selected block.

A substrate potential control circuit 18 controls a potential of a semiconductor substrate. Specifically, a double well region composed of an n-type well region and a p-type well region is formed in a p-type semiconductor substrate. When the memory cell is formed in the p-type well region, a potential of the p-type well region is controlled in accordance with an operation mode.

For example, the substrate potential control circuit 18 sets the p-type well region to 0 V at the time of read/write operation, and sets the p-type well region to 15 V or more and 40 V or less at the time of erase operation.

A potential generation circuit 19 generates a transfer potential. The transfer potential is supplied to a word line inside a block selected via the word line driver 17.

For example, at the time of read operation, the potential generation circuit 19 generates a read potential and an intermediate potential. The read potential is supplied to the selected word line inside the block selected via the word line driver 17, while the intermediate potential is supplied to the non-selected word line inside the block selected via the word line driver 17.

Further, the potential generation circuit 19 generates a write potential and an intermediate potential at the time of write operation. The write potential is supplied to the selected word line inside the block selected via the word line driver 17, while the intermediate potential is supplied to the non-selected word line inside the block selected via the word line driver 17.

A control circuit 20 controls operations of, for example, the substrate potential control circuit 18 and the potential generation circuit 19.

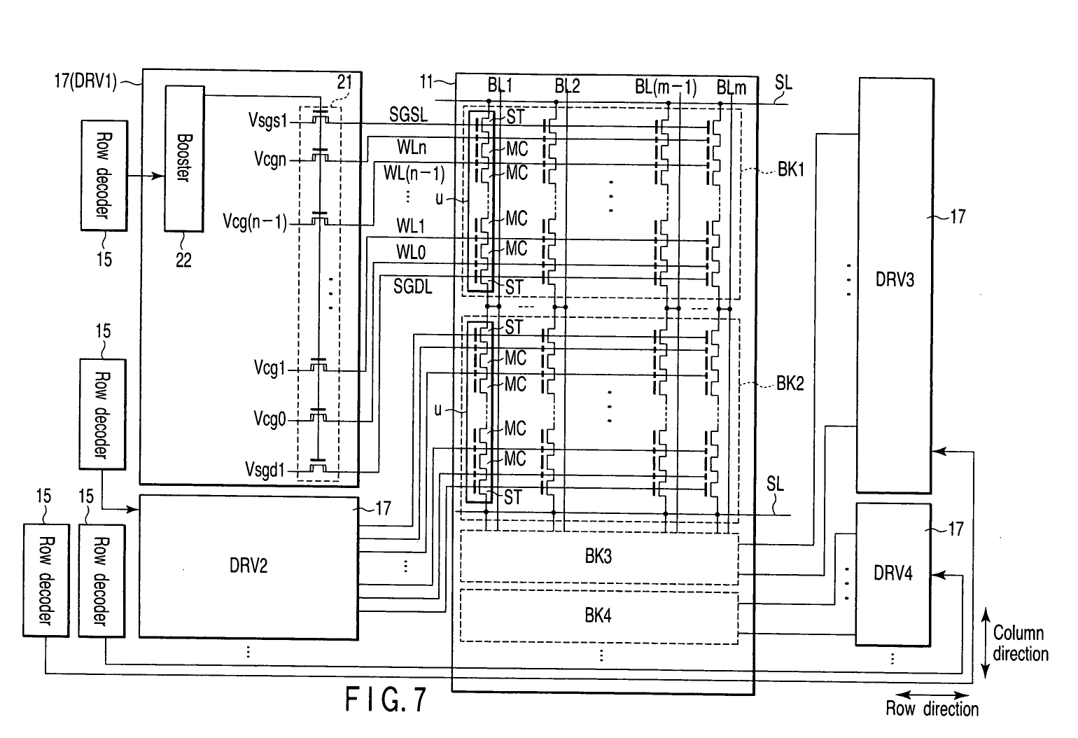

FIG. 7 shows the memory cell array of the Fin-NAND type flash memory and the word line driver.

The memory cell array 11 is composed of a plurality of blocks BK1, BK2, . . . arranged in the column direction.

Each of the blocks has a plurality of cell units U arranged in the row direction. Each of the plurality of cell units U is composed of a NAND string composed of a plurality of memory cells MC connected in series and two select gate transistors ST connected to both ends thereof one by one.

One end of the cell unit U is connected to bit lines BL1, BL2, . . . BLm, and the other end is connected to a source line SL.

A plurality of word lines WL0, WL1, . . . WL(n−1), WLn and a plurality of select gate lines SGSL, SGDL are arranged on the memory cell array 11.

For example, arranged in the block BK1 are (n+1) word lines WL0, WL1, . . . WL(n−1), WLn and two select gate lines SGSL, SGDL. The word lines WL0, WL1, WL(n−1), WLn and the select gate lines SGSL, SGDL extend in the row direction, and are connected to a transfer transistor unit 21 inside the word line driver 17 (DRV1), respectively.

The transfer transistor unit 21 is constituted by high-voltage type transistors so as to transfer, for example, a write potential which is higher than a power source voltage Vcc.

A booster 22 inside the word line driver 17 (DRV1) receives decode signals which are output from the row decoder 15. When the block BK1 is selected, the booster 22 turns the transfer transistor unit 21 on, while when the block BK1 is not selected, the booster 22 turns the transfer transistor unit 21 off.

Here, data writing to the Fin-type memory cell will be described in detail. However, in the brief description, the data writing is performed by applying a write potential to two word lines existing on both ends of a selected Fin-type memory cell.

For example, assume that the data writing is executed to the memory cell MC nearest the bit lines BL1, BL2, . . . , BLm of the cell unit U inside the block BK1. In this case, potentials Vcg0, Vcg1 to be applied to two word lines WL0, WL1 are set to the write potential, while potentials Vcg2, . . . , Vcgn applied to the other word lines WL2, . . . , WLn are set to the transfer potential turning the Fin-type memory cell MC on regardless of data stored in it.

Further, potentials Vsgs, Vsgd to be applied to the select gate lines SGSL, SGDL are set to a potential turning the select gate transistor ST on.

### B. Structure (Layout)

There will be described a structure (layout) of a cell unit of a Fin-NAND type flash memory according to an embodiment of the invention.

### B-1 First Example

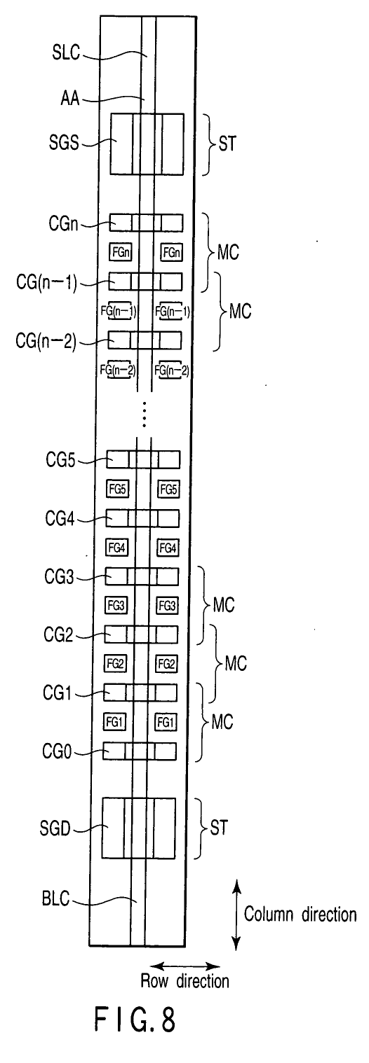

FIG. 8 shows a first example of the layout of the cell unit.

A fin-shaped active area AA extending in the column direction is arranged on a semiconductor substrate. A width of the active area AA is constant, and a pattern results in a line & space as the whole of the memory cell array.

The floating gates FG1, FG2, . . . , FGn and the control gate electrodes CG0, CG1, . . . , CGn are alternately arranged in the longitudinal direction along two side surfaces of the active area AA opposite to each other.

One of the Fin-type memory cells MC is composed of total two floating gates arranged at both side surfaces of the active area AA one by one, and two control gate electrodes arranged at the position adjacent thereto.

For example, a memory cell MC nearest a bit line contact part BLC is composed of two floating gates FG1 arranged at both side surfaces of the active area AA, and two control gate electrodes CG0, CG1 arranged at the positions adjacent thereto.

In the present example, a NAND string is composed of n Fin-type memory cells MC connected in series. The NAND string terminates at the control gate electrodes CG0, CGn.

At both ends of the NAND string, total two select gate transistors ST are arranged one by one each.

The select gate transistor ST has select gate electrodes SGS, SGD with the same shape as the control gate electrodes CG0, CG1, . . . , CGn of the Fin-type memory cell MC.

However, a channel length of the select gate transistor ST, that is, a length of the select gate electrodes SGS, SGD in the column direction is longer than that of the control gate electrodes CG0, CG1, . . . , CGn of the Fin-type memory cell MC.

The active area AA at one end of the cell unit comes to a source line contact part SLC to which the source line is connected, while the active area AA at the other end comes to a bit line contact part BLC to which the bit line is connected.

Note that the control gate electrodes CG0, CG1, . . . , CGn and the select gate electrodes SGS, SGD may be shaped in a bridge, and like the floating gates FG1, FG2, . . . , FGn, each may be arranged independently at one side surface of the active area AA.

According to such a layout, actually, it is possible to constitute a NAND type flash memory by using the Fin-type memory cell according to the embodiment of the invention.

### B-2 Second Example

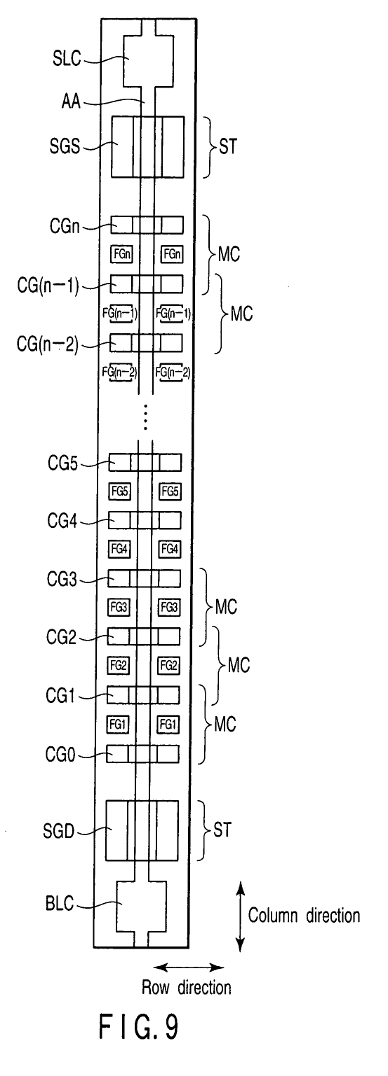

FIG. 9 shows a second example of the layout of the cell unit.

The second example is a modified example of the first example.

The layout of the second example is the same as that of the first example except that the source line contact part SLC and the bit line contact part BLC have different shapes.

In the second example, a fringe is provided to each of the source line contact part SLC and the bit line contact part BLC of the active area AA such that the source line and the bit line come into easily contact with the active area AA.

As a consequence, even if there occurs deviation in matching between the source line contact part SLC or the bit line contact part BLC and the contact holes, loose connection between the source line or the bit line and the active area AA is hard to occur.

### B-3 Third Example

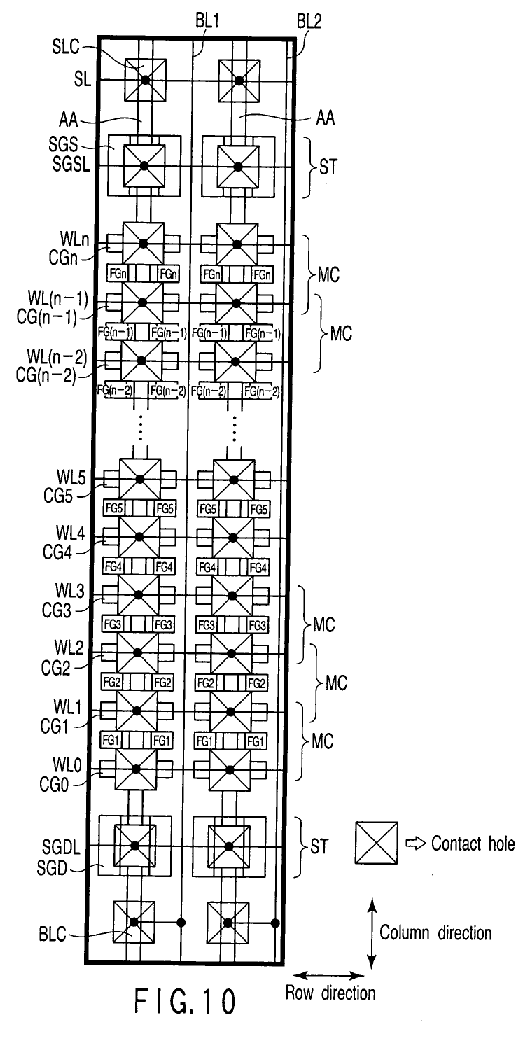

FIG. 10 shows a third example of the layout of the cell unit.

The third example is configured in such a manner that the layout of the word line, the select gate line, the source line and the bit line is further added to the layout of the first example. The layout of the cell unit is the same as the first example.

Naturally, it is possible to combine the layout of the third example with the layout of the second example.

The contact holes are arranged on the control gate electrodes CG0, CG1, . . . , CGn. The word lines WL0, WL1, . . . , WLn extending in the row direction are connected to the control gate electrodes CG0, CG1, CGn via the contact holes.

Also on the select gate electrodes SGS, SGD, the contact holes are arranged. The select gate lines SGSL, SGDL extend in the row direction, and are connected to the select gate electrodes SGS, SGD via the contact holes.

As for the word lines WL0, WL1, . . . , WLn and the select gate lines SGSL, SGDL, it is possible to adopt a low resistance wiring structure such as a silicide structure or a metal structure.

The source line SL is connected on the source line contact part SLC via the contact hole. The source line SL extends in the row direction. The bit lines BL1, BL2, . . . are connected on the bit line contact part BLC via the contact holes. The bit lines BL1, BL2, extend in the column direction.

In the layout of the present example, the floating gates FG1, FG2, . . . , FGn and the control gate electrodes CG0, CG1, . . . , CGn are alternately arranged in the longitudinal direction of the active area AA.

As a result, assuming that, for example, a pitch to arrange them alternately is made 2L, it is possible to enlarge the size of the contact hole on the control gate electrodes CG0, CG1, . . . , CGn in the column direction up to the maximum value of 3L. Further, also the width of the word lines WL0, WL1, . . . , WLn can be widened up to the maximum value of 3L.

However, the width of the floating gates FG1, FG2, . . . , FGn and the control gate electrodes CG0, CG1, . . . , CGn in the column direction is made L, and a space between the both is also made L.

In the same way as above, as for the contact holes on the select gate electrodes SGS, SGD of the select gate transistor ST and the select gate lines SGSL, SGDL, it is possible to enlarge the size in the column direction.

Therefore, even if the Fin-type memory cell is miniaturized, it is possible to realize high-speed memory operation without increasing remarkably a contact resistance and a wiring resistance.

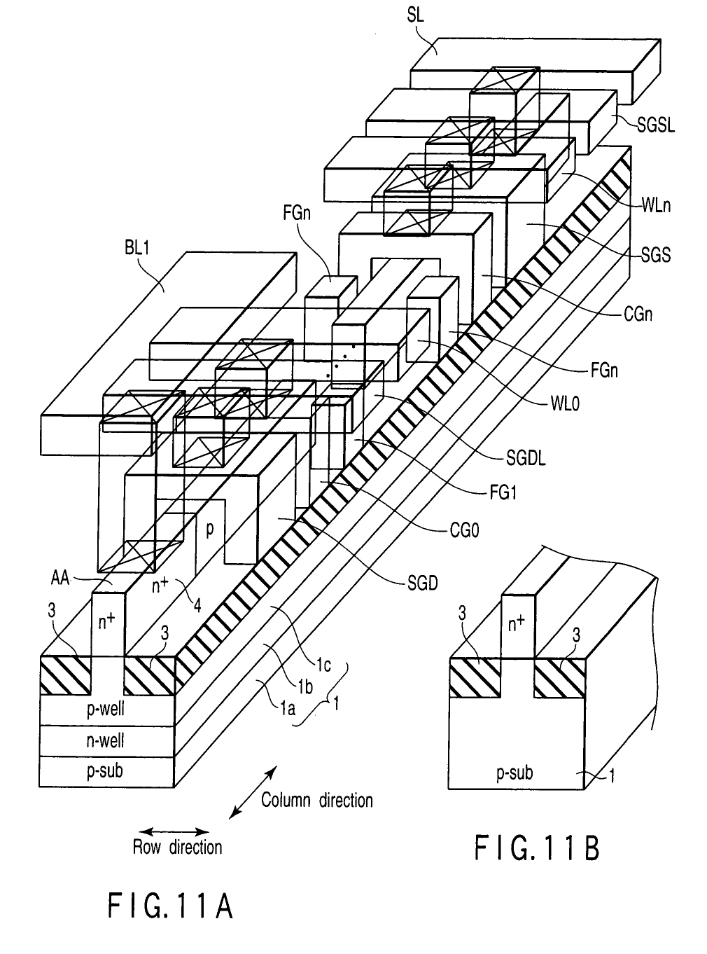

FIGS. 11A and 11B each show a structure example in the case where the layout of FIG. 10 is three-dimensionally formed.

A semiconductor substrate 1a is a p-type semiconductor substrate. For example, as shown in FIG. 11A, a double well region composed of an n-type well region 1b and a p-type well region 1c is formed in the surface region of the semiconductor substrate 1a. The fin-shaped active area AA is arranged in the p-type well region 1c.

For example, as shown in FIG. 11B, it is permissible that the double well region is omitted and the fin-shaped active area AA is formed in the p-type semiconductor substrate 1.

At a lower part of the fin-shaped active area AA, there is formed an element isolation insulating layer 3 with a shallow trench isolation (STI) structure so as to sandwich it.

The select gate transistor ST has a diffusion layer 4 in the active area AA. The diffusion layer 4 is formed below the source line contact part SLC and the bit line contact part BLC.

The diffusion layer of the source side select gate transistor ST of the NAND string comes to an n⁺ type source diffusion layer. The source line SL is connected to the n⁺ type source diffusion layer of the source side select gate transistor ST.

The diffusion layer of the drain side select gate transistor ST of the NAND string comes to an n⁺ type drain diffusion layer 4. The bit line BL is connected to the n⁺ type drain diffusion layer 4 of the drain side select gate transistor ST.

In the active area AA, respective diffusion layers may be formed or may not be formed between the memory cells constituting the NAND string and between the memory cell and the select gate transistor.

### B-4 Fourth Example

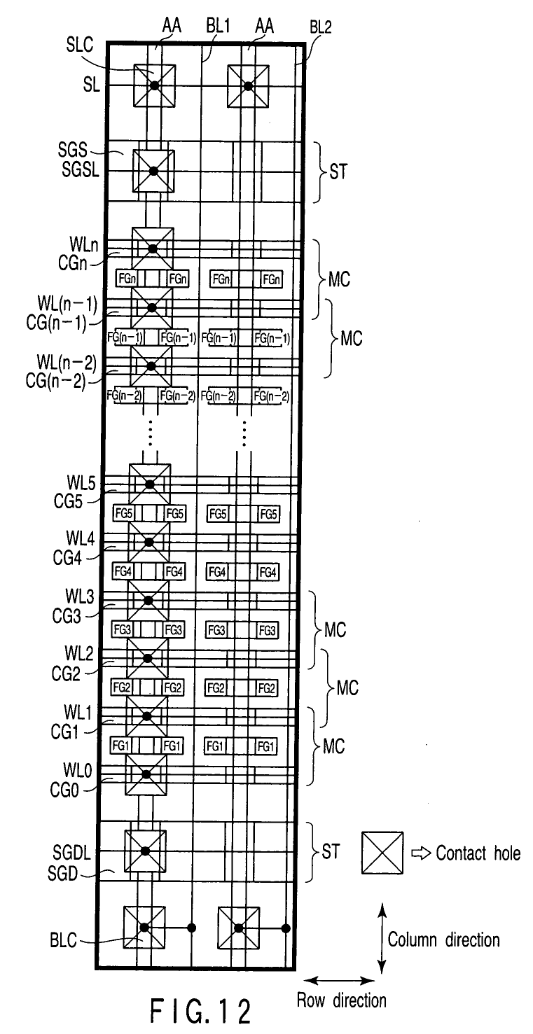

FIG. 12 shows a fourth example of the layout of the cell unit.

A fin-shaped active area AA extending in the column direction is arranged on a semiconductor substrate. A width of the active area AA is constant, and a pattern results in a line & space as the whole memory cell array.

The floating gates FG1, FG2, . . . , FGn and the control gate electrodes CG0, CG1, . . . , CGn are alternately arranged in the longitudinal direction along two side surfaces of the active area AA opposite to each other.

One Fin-type memory cell MC is composed of total two floating gates arranged at both side surfaces of the active area AA one by one, and two control gate electrodes arranged at the position adjacent thereto.

In the present example, a NAND string is composed of n Fin-type memory cells MC connected in series. The NAND string terminates at the control gate electrodes CG0, CGn.

Total two select gate transistors ST are arranged at both ends of the NAND string one by one each.

The select gate transistor ST has select gate electrodes SGS, SGD with the same shape as that of the control gate electrodes CG0, CG1, . . . , CGn of the Fin-type memory cell MC.

However, a channel length of the select gate transistor ST, that is, a length of the select gate electrodes SGS, SGD in the column direction is longer than that of the control gate electrodes CG0, CG1, . . . , CGn of the Fin-type memory cell MC.

The active area AA at one end of the cell unit comes to a source line contact part SLC to which the source line is connected, while the active area AA at the other end comes to a bit line contact part BLC to which the bit line is connected.

In the present example, the control gate electrodes CG0, CG1, . . . , CGn arranged at both side surfaces of the plurality of active areas AA are connected mutually in the same layer. That is, the control gate electrodes CG0, CG1, . . . , CGn have a bridge shape of straddling the plurality of active areas AA.

The contact holes are arranged on the control gate electrodes CG0, CG1, . . . , CGn. The word lines WL0, WL1, . . . , WLn extending in the row direction are connected to the control gate electrodes CG0, CG1, CGn via the contact holes.

Also on the select gate electrodes SGS, SGD, the contact holes are arranged. The select gate lines SGSL, SGDL extending in the row direction are connected to the select gate electrodes SGS, SGD via the contact holes.

The contact holes on the control gate electrodes CG0, CG1, . . . , CGn and the select gate electrodes SGS, SGD are arranged with wider pitch than that of the active area AA.

However, these contact holes may be arranged with the same pitch as the active area AA.

As for the word lines WL0, WL1, . . . , WLn and the select gate lines SGSL, SGDL, it is possible to adopt a low resistance wiring structure such as a silicide structure or a metal structure.

The source line SL is connected on the source line contact part SLC via the contact hole. The source line SL extends in the row direction. The bit lines BL1, BL2, . . . are connected on the bit line contact part BLC via the contact holes. The bit lines BL1, BL2, . . . extend in the column direction.

In the layout of the present example, the floating gates FG1, FG2, . . . , FGn and the control gate electrodes CG0, CG1, . . . , CGn are alternately arranged in the longitudinal direction of the active area AA.

As a result, for example, when a pitch to arrange them alternately is made 2L like the first example, it is possible to enlarge the size of the contact hole on the control gate electrodes CG0, CG1, . . . , CGn in the column direction up to the maximum value of 3L. Further, the width of the word lines WL0, WL1, . . . , WLn can be also widened up to the maximum value of 3L.

However, the width of the floating gates FG1, FG2, . . . , FGn and the control gate electrodes CG0, CG1, . . . , CGn in the column direction is made L, and a space between the both is also made L.

In the same way as above, as for the contact hole on the select gate electrodes SGS, SGD of the select gate transistor ST and the select gate lines SGSL, SGDL, it is possible to enlarge the size in the column direction.

According to such a layout, actually, it is possible to constitute the NAND type flash memory by using the Fin-type memory cell according to the embodiment of the invention.

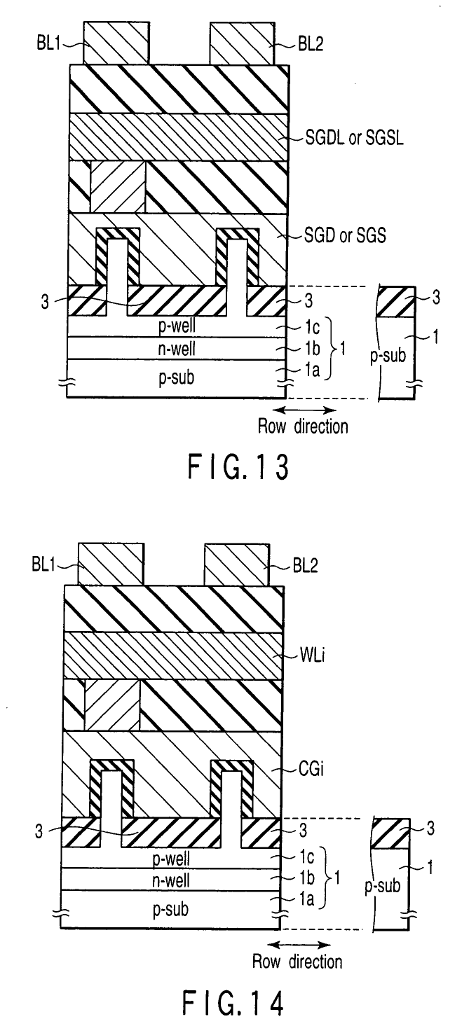

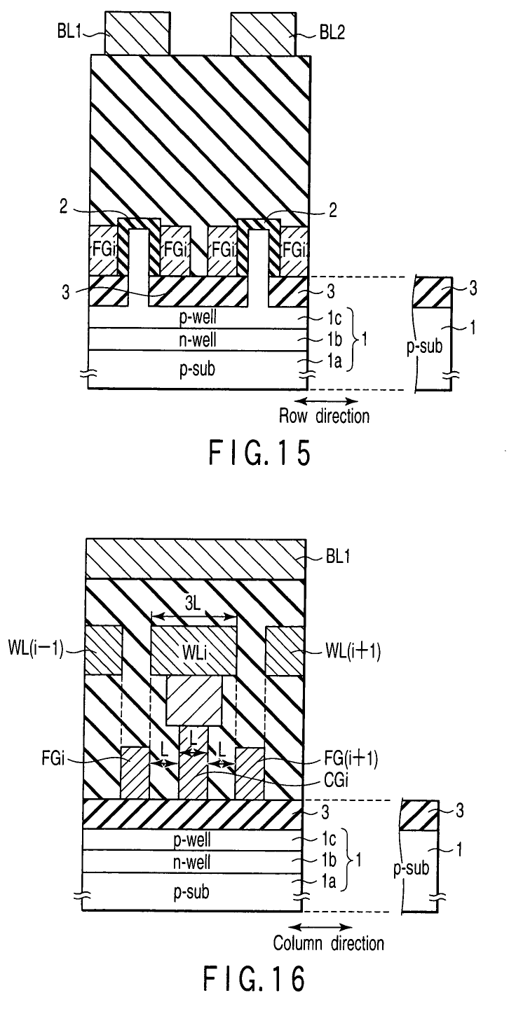

FIGS. 13 to 16 show examples of the device structure in the case where the layout of FIG. 12 is three-dimensionally formed.

A semiconductor substrate 1a is a p-type semiconductor substrate, and a double well region composed of an n-type well region 1b and a p-type well region 1c is formed in the surface region of the semiconductor substrate 1a. At a lower part of the fin-shaped active area AA, there is formed an element isolation insulating layer 3 with a shallow trench isolation (STI) structure so as to sandwich it.

Of course, it is permissible that the double well region is omitted and the fin-shaped active area AA is formed in the p-type semiconductor substrate 1.

### B-5 Fifth Example

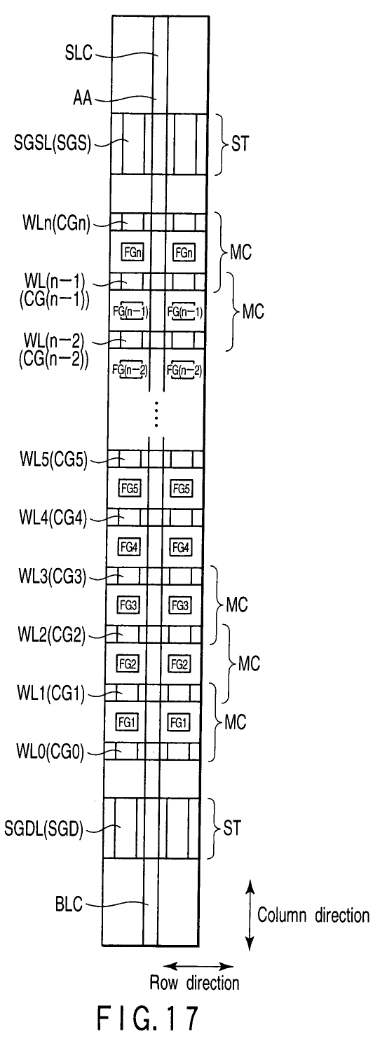

FIG. 17 shows a fifth example of the layout of the cell unit.

A fin-shaped active area AA extending in the column direction is arranged on a semiconductor substrate. A width of the active area AA is constant, and a pattern results in a line & space as the whole of the memory cell array.

The floating gates FG1, FG2, . . . , FGn and the control gate electrodes CG0, CG1, . . . , CGn are alternately arranged in the longitudinal direction along two side surfaces of the active area AA opposite to each other.

One Fin-type memory cell MC is composed of total two floating gates arranged at both side surfaces of the active area AA one by one, and two control gate electrodes arranged at the position adjacent thereto.

In the present example, a NAND string is composed of n Fin-type memory cells MC connected in series. The NAND string terminates at the control gate electrodes CG0, CGn.

Total two select gate transistors ST are arranged at both ends of the NAND string one by one each.

The select gate transistor ST has select gate electrodes SGS, SGD with the same shape as the control gate electrodes CG0, CG1, . . . , CGn of the Fin-type memory cell MC.

However, a channel length of the select gate transistor ST, that is, a length of the select gate electrodes SGS, SGD in the column direction is longer than that of the control gate electrodes CG0, CG1, . . . , CGn of the Fin-type memory cell MC.

The active area AA at one end of the cell unit comes to a source line contact part SLC to which the source line is connected, while the active area AA at the other end comes to a bit line contact part BLC to which the bit line is connected.

The control gate electrodes CG0, CG1, . . . , CGn and the select gate electrodes SGS, SGD may have a bridge shape of straddling one or more active areas AA, or each may be arranged independently at one side surface of the active area AA, like the floating gates FG1, FG2, . . . , FGn.

The word lines WL0, WL1, . . . , WLn are directly formed on the control gate electrodes CG0, CG1, . . . , CGn. Also, the select gate lines SGSL, SGDL are directly formed on the select gate electrodes SGS, SGD.

That is, in the present example, no contact holes exist among the word lines WL0, WL1, . . . , WLn and the control gate electrodes CG0, CG1, . . . , CGn, and among the select gate lines SGSL, SGDL and the select gate electrodes SGS, SGD.

Therefore, as compared with the first to the fourth examples, the fifth example can achieve simplification of the process and reduction of the manufacturing cost since it is possible to omit steps for forming these contact holes.

According to such a layout, actually, it is also possible to constitute the NAND type flash memory by using the Fin-type memory cell according to the embodiment of the invention.

### B-6 Sixth Example

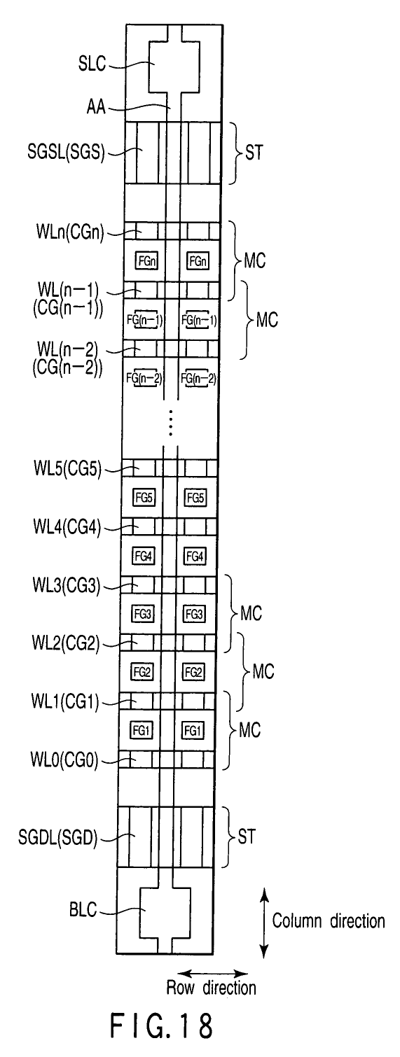

FIG. 18 shows a sixth example of the layout of the cell unit.

The sixth example is a modified example of the fifth example.

The layout of the sixth example is the same as that of the fifth example except that the source line contact part SLC and the bit line contact part BLC have different shapes.

In the sixth example, a fringe is provided to each of the source line contact part SLC and the bit line contact part BLC of the active area AA such that the source line and the bit line come into easily contact with the active area AA.

As a consequence, even if there occurs deviation in matching between the source line contact part SLC or the bit line contact part BLC and the contact holes, loose connection between the source line or the bit line and the active area AA is hard to occur.

### B-7 Seventh Example

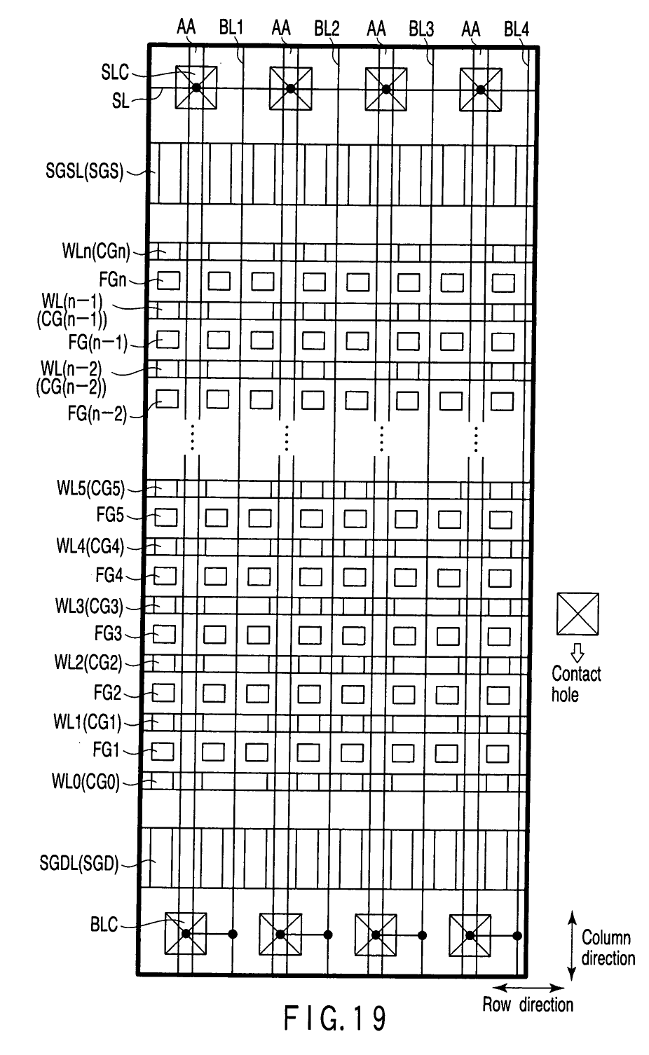

FIG. 19 shows a seventh example of the layout of the cell unit.

The seventh example is configured in such a manner that the layout of the word line, the select gate line, the source line and the bit line is further added to the layout of the fifth example.

The layout of the cell unit is the same as that of the fifth example.

The word lines WL0, WL1, . . . , WLn are directly formed on the control gate electrodes CG0, CG1, . . . , CGn. Also, the select gate lines SGSL, SGDL are directly formed on the select gate electrodes SGS, SGD.

That is, in the present example, no contact holes exist among the word lines WL0, WL1, . . . , WLn and the control gate electrodes CG0, CG1, . . . , CGn, and among the select gate lines SGSL, SGDL and the select gate electrodes SGS, SGD.

As for the word lines WL0, WL1, . . . , WLn and the select gate lines SGSL, SGDL, it is possible to adopt a low resistance wiring structure such as a silicide structure or a metal structure.

The source line SL is connected on the source line contact part SLC via the contact hole. The source line SL extends in the row direction. The bit lines BL1, BL2, BL3 . . . are connected on the bit line contact part BLC via the contact holes. The bit lines BL1, BL2, BL3 . . . extend in the column direction.

In the layout of the example, the floating gates FG1, FG2, . . . , FGn and the control gate electrodes CG0, CG1, . . . , CGn are alternately arranged in the longitudinal direction of the active area AA.

As a result, for example, when a pitch to arrange them alternately is made 2L like the first example, it is possible to enlarge the size of the contact hole on the control gate electrodes CG0, CG1, . . . , CGn in the column direction up to the maximum value of 3L. Further, the width of the word lines WL0, WL1, . . . , WLn can be also widened up to the maximum value of 3L.

However, the width of the floating gates FG1, FG2, . . . , FGn and the control gate electrodes CG0, CG1, . . . , CGn in the column direction is made L, and a space between the both is also made L.

In the same way as above, as for the contact holes on the select gate electrodes SGS, SGD of the select gate transistor ST and the select gate lines SGSL, SGDL, it is possible to enlarge the size in the column direction.

Accordingly, even if the Fin-type memory cell is miniaturized, it is possible to realize high-speed memory operation without increasing remarkably a contact resistance and a wiring resistance.

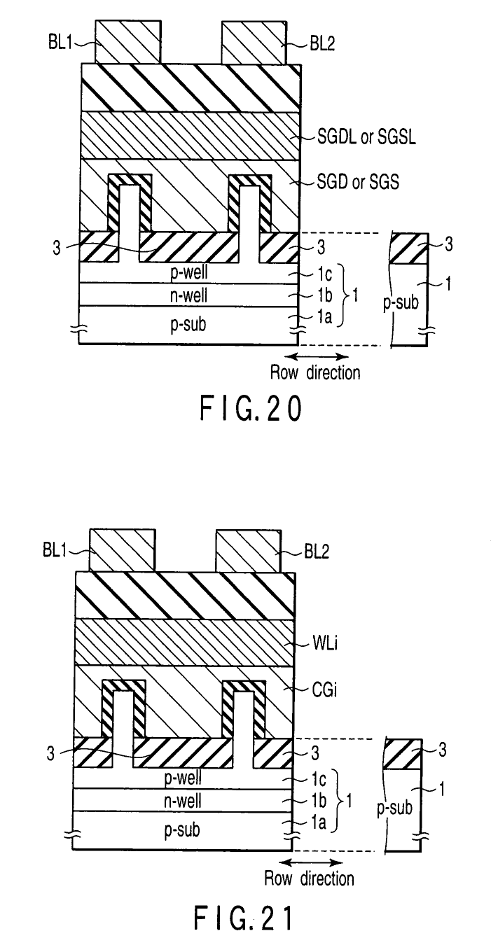

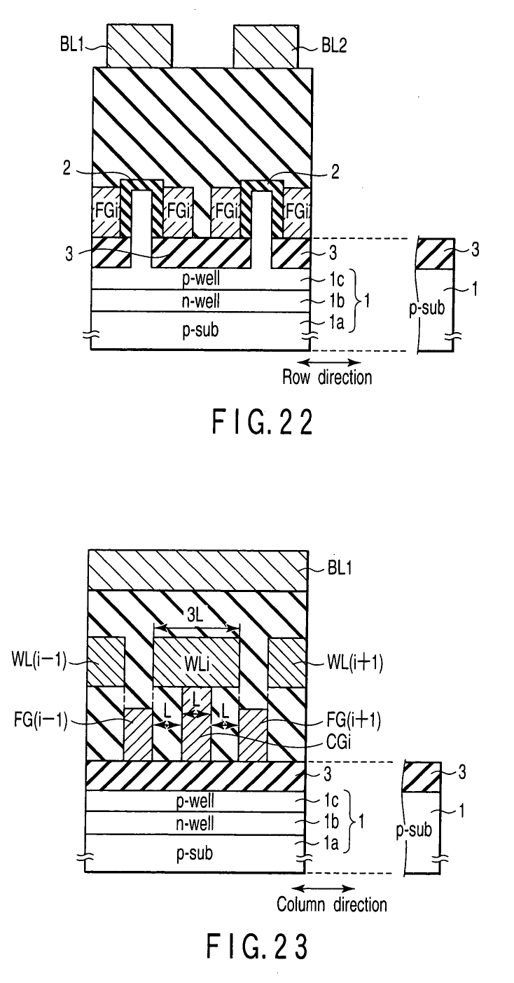

FIGS. 20 to 23 show examples of the device structure in the case where the layout of FIG. 19 is three-dimensionally formed.

A semiconductor substrate 1a is a p-type semiconductor substrate, and a double well region composed of an n-type well region 1b and a p-type well region 1c is formed in the surface region of the semiconductor substrate 1a. At a lower part of the fin-shaped active area AA, an element isolation insulating layer 3 with a shallow trench isolation (STI) structure is formed.

Of course, it is acceptable that the double well region is omitted and the fin-shaped active area AA is formed in the p-type semiconductor substrate 1.

### C. Basic Operation

There will be described a basic operation of the Fin-NAND type flash memory according to the embodiment of the invention.

The Fin-type memory cell according to the embodiment of the invention can cope with both types of a 2-level type for storing 1 bit data in one cell and a multi-level type for storing data of 2 bits or more in one cell. Further, it is also possible to set freely threshold distribution of data values to be stored in the Fin-type memory cell.

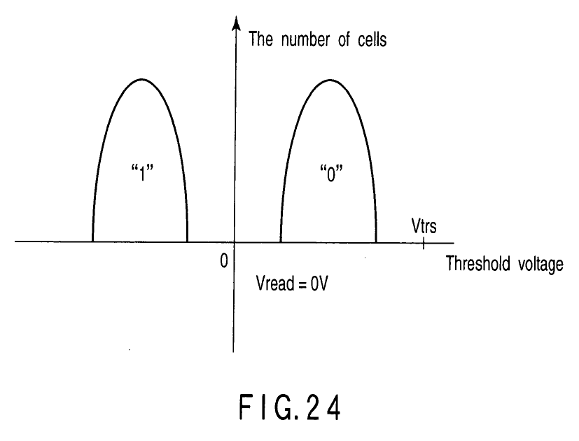

However, for ease of explanation, it is provided herein that the Fin-type memory cell is the 2-level type, and further, as shown in FIG. 24, a threshold voltage of the Fin-type memory cell for storing “1”-data is less than 0 V while a threshold voltage of the Fin-type memory cell for storing “0”-data exceeds 0 V.

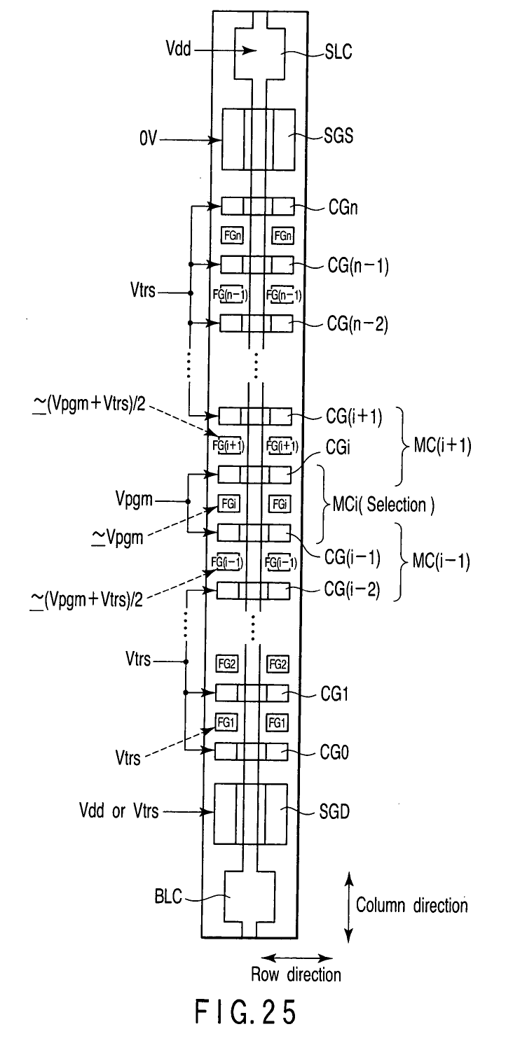

### C-1 Write Operation FIG. 25 shows a potential relation inside the cell unit at the time of write operation.

When executing a data writing to a Fin-type memory cell MCi, control gate electrodes CG(i−1), CG1 existing on both sides of a floating gate FGi are set to a write potential Vpgm. At this time, the floating gate FGi following the potential of the control gate electrodes CG(i−1), CG1 comes to a value near the write potential Vpgm.

A transfer potential Vtrs for turning the Fin-type memory cell on is applied to all the remaining control gate electrodes CG1, . . . , CG(i−2), CG(i+1), . . . CGn except for the control gate electrodes CG(i−1), CG1, respectively.

A grounding potential (0 V) for turning the select gate transistor off is applied to the select gate electrode SGS of the source side select gate transistor.

A power source potential Vdd for turning the select gate transistor on is applied to the select gate electrode SGD of the drain side select gate transistor.

Then, write data is transferred to the cell unit via the bit line contact part BLC from the bit line.

When the write data is “1”, the bit line is a power source potential Vdd, for example. For this reason, the power source potential Vdd turns the select gate transistor SGS off, and as a result, all the memory cells MC1, MC2, . . . , MCn are in a floating state. That is, the Fin-type memory cell MCi does not differ from an initial state (erase state) maintained, so that “1”-data is written in the Fin-type memory cell MCi.

When the write data is “0”, the bit line is a grounding potential, i.e., 0 V, for example. For this reason, the grounding potential of 0 V is transferred to the selected Fin-type memory cell MCi. That is, electric charge (electron) is injected to the floating gate FGi of the Fin-type memory cell MCi, and then, the threshold voltage rises, so that “0”-data is written in the Fin-type memory cell MCi.

Here, at the time of the write operation, the potentials of the floating gates FG(i−1), FG(i+1) of the non-selected Fin-type memory cells MC(i−1), MC(i+1) adjacent to the selected Fin-type memory cell MCi come to values near (Vpgm+Vtrs)/2 each.

Therefore, conditions of the write potential Vpgm, the transfer potential Vtrs, the thickness of the tunnel insulating film and the like are set in order that error writing to the non-selected Fin-type memory cells MC(i−1), MC(i+1) does not occur and that the data writing does not occur depending on a certain intermediate potential (Vpgm+Vtrs)/2.

For example, assume that charge injections due to tunnel phenomena are generated at the time when an electric field generated on the tunnel insulating film exceeds 10 MV/cm. In this case, since the selected Fin-type memory cell MCi must be set in order to control the threshold voltage due to the charge injection, it is necessary for the write potential Vpgm to be set to a value exceeding 10 V if the thickness of the tunnel insulating film is 10 nm.

On the other hand, as for the non-selected Fin-type memory cell other than the Fin-type memory cell MCi, threshold change due to the charge injection should not be generated, and therefore, it is necessary for the transfer potential Vtrs to be set to a value of 10 V or less. Also, the Fin-type memory cells MC(i−1), MC(i+1) adjacent to the Fin-type memory cell MCi are non-selected ones, and therefore, it is also necessary for the intermediate potential (Vpgm+Vtrs)/2 to be a value of 10 V or less.

According to the above, provided that, for example, the transfer potential Vtrs is 3 V, the write potential Vpgm can be set to a value in the range of 10 V<Vpgm<17 V. Contrary to this, as the write potential Vpgm is brought near 10 V, it is possible to enlarge the value of the transfer potential Vtrs.

Since these potential relations are determined while getting involved in various elements, it is not limited to this.

Further, the width of the active area is preferably made wider than that of the active area of the Fin-FET constituting the logic circuit.

Furthermore, in the case where the write data is “1”, the value of the power supply potential Vdd to be applied to the bit line contact part BLC is determined while considering various conditions, like the above-described transfer potential Vtrs. As one example, the condition of the write operation is set so as to satisfy Vpgm−Vdd<(Vpgm+Vtrs)/2, if Vtrs is applied to the select gate transistor SGD.

### C-2 Read Operation

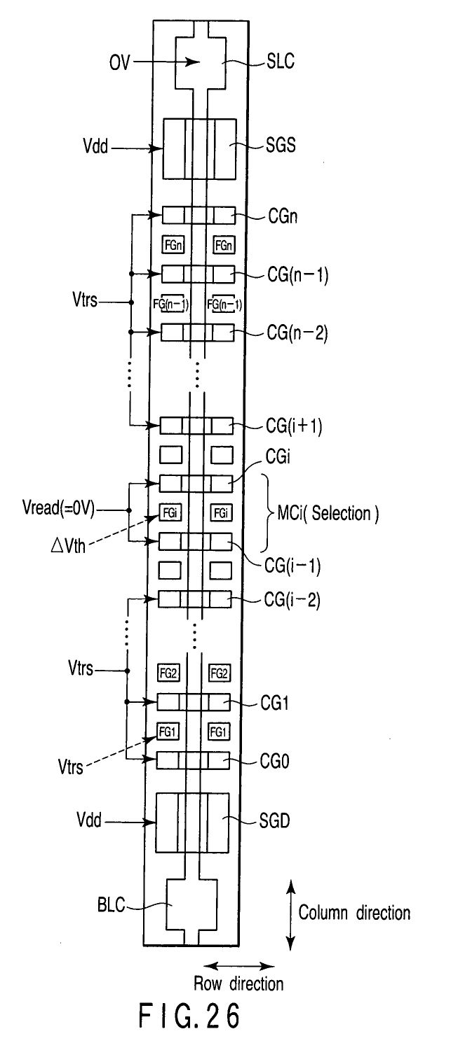

FIG. 26 shows the potential relation inside the cell unit at the time of read operation.

When executing the data reading to the Fin-type memory cell MCi, the control gate electrodes CG(i−1), CG1 existing on both sides of the floating gate FGi are set to the read potential Vread.

Since it is presupposed that a data value of the Fin-type memory cell shows the threshold distribution of FIG. 24 in the embodiment, the read potential Vread comes to 0 V. When the threshold distribution is changed, the value of the read potential Vread is changed according to its change. Further, also when the 2-level type is changed to the multi-level type, the value of the read potential Vread is changed.

In this case, as apparent from the threshold distribution of FIG. 24, the selected Fin-type memory cell MCi is turned ON/OFF in accordance with the data value stored therein.

A transfer potential Vtrs for turning the Fin-type memory cell on is applied to all the remaining control gate electrodes CG1, . . . , CG(i−2), CG(i+1), . . . CGn except for the control gate electrodes CG(i−1), CG1, respectively.

A power source potential Vdd for turning the select gate transistor on is applied to the select gate electrode SGD of the drain side select gate transistor and to the select gate electrode SGS of the source side select gate transistor.

Therefore, in accordance with the data stored in the Fin-type memory cell MCi, the value of the current flowing in the whole cell unit including thereof changes.

That is, when the data stored in the Fin-type memory cell MCi is “0”, the current scarcely flows in the cell unit. Contrary to this, when the data stored in the Fin-type memory cell MCi is “1”, the large current flows in the cell unit.

Accordingly, by using, for example, a sense amplifier to be connected to the bit line, the value of the read data is determined by detecting the current fluctuation.

### C-3 Erase Operation

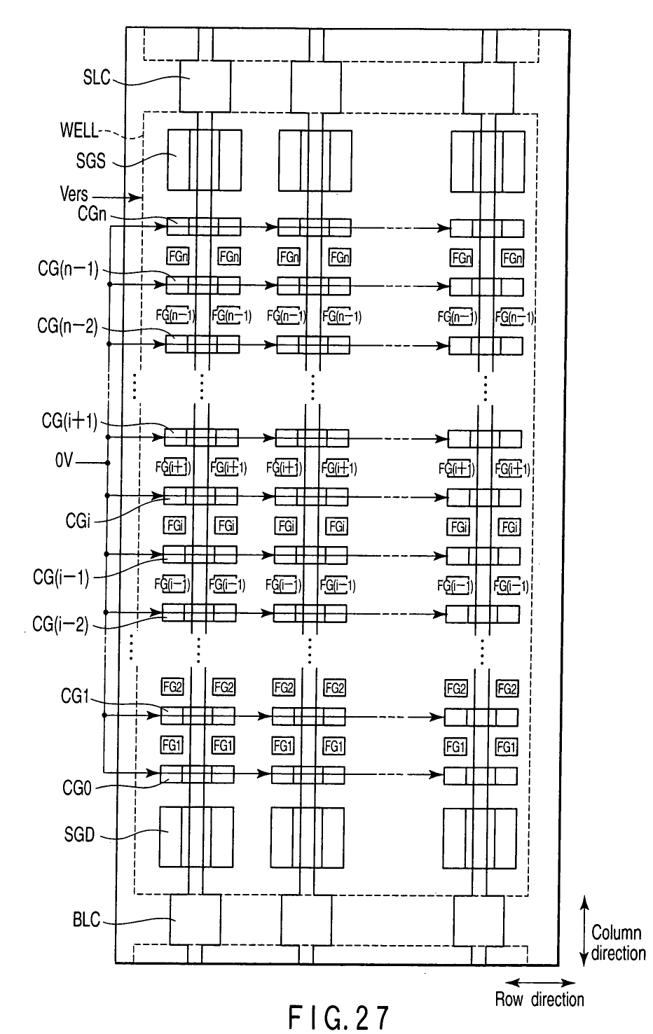

FIG. 27 shows a potential relation inside the cell unit at the time of erase operation.

The erase operation performed, for example, on lumped block unit. In this case, all the control gate electrodes CG1, CG2, . . . , CGn inside the selected block are set to the grounding potential of 0 V, and a well region WELL where all the Fin-type memory cells inside the selected block are arranged is set to the erase potential Vers.

Consequently, in all the Fin-type memory cells inside the selected block, movement of the electric charge is generated from the floating gates FG1, FG2, . . . , FGn to the well region (including the fin-shaped active area AA) WELL, batch erasing of the data of the Fin-type memory cell is completed.

Note that the erase operation can be performed simultaneously to a plurality of blocks or the whole blocks.

On the other hand, all the control gate electrodes are opened in unselected block.

### D. Others

When, in the existing NAND type flash memory, the threshold distribution of the memory cell is set, for example, in the range of −1 V to 3 V, there are provided four threshold distributions in the range to put the threshold distribution to multi-level of (00), (01), (10) and (11). On the other hand, when setting the threshold distribution of the memory cell in the range of 0 V to 1 V, there are provided two threshold distributions in the range to put the threshold distribution to 2-level type. In the Fin-type memory cell according to the embodiment of the invention, it is possible to determine the specification while being caused to correspond with such an existing NAND type flash memory.

### (3) Multi-level Fin-NAND Type Flash Memory

In the above-described Fin-NAND type flash memory, a plurality of cell units are formed in the column direction and only one cell unit is formed in the row direction in one active area.

To the contrary, hereinafter, there will be proposed a technique for forming a plurality of cell unit in the row direction with respect to one active area.

Specifically, each cell unit is formed on both mutually opposite side surfaces of the active area. That is, data is stored independently in a floating gate arranged at one of two side surfaces of the active area and in a floating gate arranged at the other thereof.

### A. Whole View

The multi-level type has, for example, a block constitution as shown in FIG. 6, like the 2-level type. Further, a memory cell array comes to one as shown in FIG. 7.

### B. Basic Structure

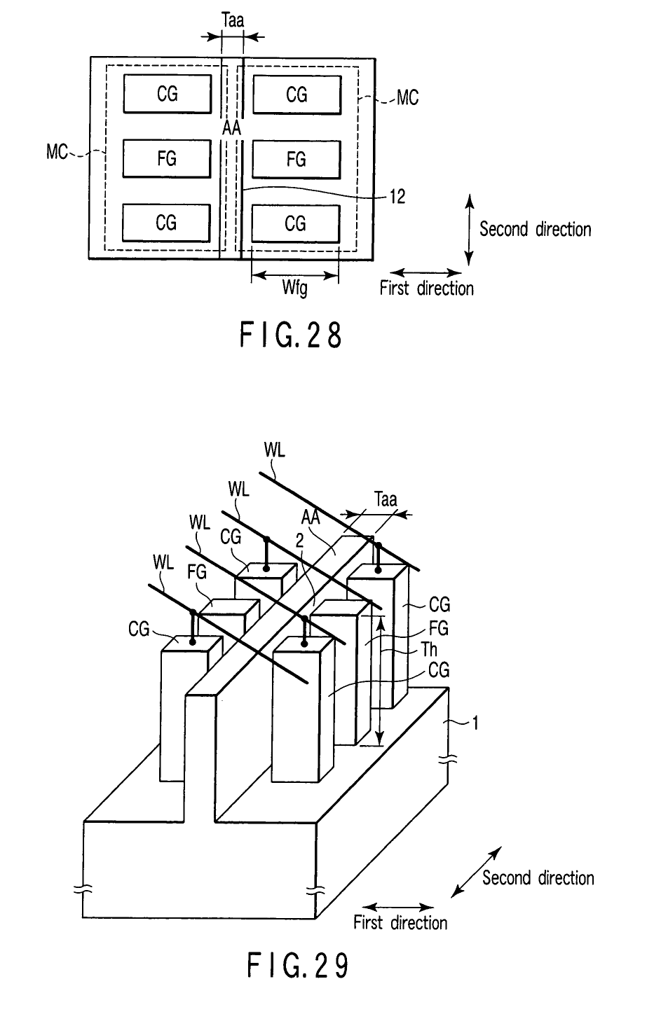

FIGS. 28 and 29 show a basic structure of a memory cell of a multi-level Fin-NAND type flash memory according to one embodiment of the invention.

The Fin-type memory cell MC is formed in a fin-shaped active area AA on a semiconductor substrate 1. A longitudinal direction of the active area AA is a column direction, and a thickness of the active area AA in a row direction is set to Taa.

Floating gates FG are arranged along both side surfaces of the active area AA. A tunnel insulating film 2 made of, for example, silicon oxide is arranged between the floating gate FG and the active area AA.

The floating gate FG arranged at one of two side surfaces of the active area AA and the floating gate FG arranged at the other are separated from each other, and data is written independently.

Two control gate electrodes CG sandwiching the floating gate FG are arranged in the longitudinal direction of the active area AA to the floating gate FG.

The control gate electrode CG arranged at one of two side surfaces of the active area AA and the control gate electrode CG arranged at the other are separated from each other, and they are connected to word lines WL independently.

In the present embodiment, one Fin-type memory cell is composed of a floating gate FG arranged at one side surface of the active area AA, and two control gate electrodes CG sandwiching the floating gate FG.

Characteristic of this structure is that respective different Fin-type memory cells are arranged at both side surfaces of the active area AA. That is, respective NAND strings are formed at both side surfaces of the active area AA.

According to such a structure, two times of memory capacity can be achieved without increasing an area of the memory cell array as compared with the 2-level Fin-NAND type flash memory.

### C. Structure (Layout)

There will be described a structure (layout) of the cell unit of the multi-level Fin-NAND type flash memory according to the embodiment of the invention.

As for the multi-level type, it should be noted that since respective NAND strings are formed at both side surfaces of the active area, it is not possible to perform layout of the word line in the direction orthogonal to the longitudinal direction of the active area.

Accordingly, particularly, description will be given mainly on the layout of the word line hereinafter.

### C-1 First Example

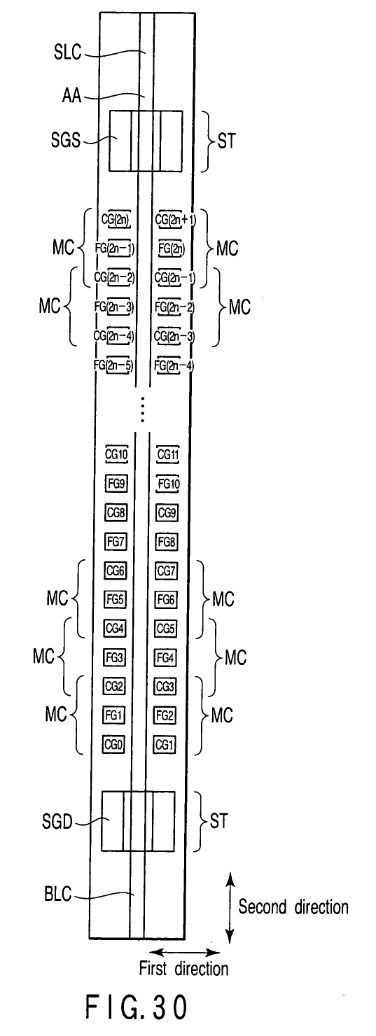

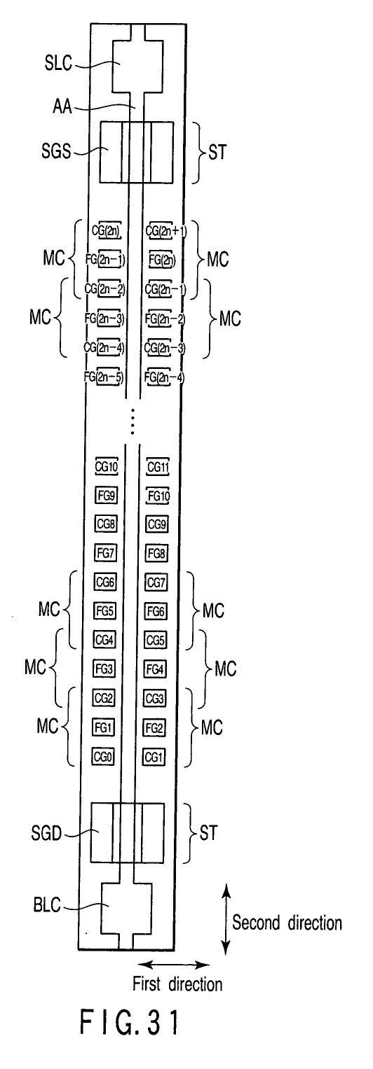

FIG. 30 shows a first example of the layout of the cell unit.

A fin-shaped active area AA extending in the column direction is arranged on a semiconductor substrate. A width of the active area AA is constant, and a pattern results in a line & space as the whole of the memory cell array.

The floating gates FG1, FG2, . . . , FG(2n) and the control gate electrodes CG0, CG1, . . . , CG(2n+1) are alternately arranged in the longitudinal direction along two side surfaces of the active area AA opposite to each other.

One Fin-type memory cell MC is composed of one floating gate arranged at one side surface of the active area AA, and two control gate electrodes sandwiching the one floating gate.

For example, one of the memory cells MC nearest a bit line contact part BLC is composed of a floating gates FG1 arranged at one side surface of the active area AA and control gate electrodes CG0, CG2 sandwiching the floating gates FG1. Further, the other is composed of a floating gate FG2 arranged at one side surface of the active area AA and control gate electrodes CG1, CG3 sandwiching the floating gate FG2.

In the present embodiment, a NAND string is composed of n Fin-type memory cells MC connected in series, the Fin-type memory cells MC being respectively formed at both side surfaces of the active area AA. The NAND strings terminate at the control gate electrodes CG0, CG1, CG(2n) and CG(2n+1).

At both ends of the NAND string, total two select gate transistors ST are arranged one by one each.

Here, the select gate transistor ST is shared with two NAND strings formed at both side surfaces of the active area AA.

The select gate transistor ST has select gate electrodes SGS, SGD. The select gate electrodes SGS, SGD are, for example, different from the control gate electrodes CG0, CG1, . . . , CG(2n+1) of the Fin-type memory cell MC, and have a bridge shape of straddling the active area AA.

A channel length of the select gate transistor ST, that is, a length of the select gate electrodes SGS, SGD in the column direction is longer than that of the control gate electrodes CG0, CG1, . . . , CG(2n+1) of the Fin-type memory cell MC.

The active area AA at one end of the cell unit comes to a source line contact part SLC to which the source line is connected, while the active area AA at the other end comes to a bit line contact part BLC to which the bit line is connected.

According to such a layout, it is possible to realize the multi-level Fin-NAND type flash memory.

### C-2 Second Example

FIG. 31 shows a second example of the layout of the cell unit.

The second example is a modified example of the first example.

The layout of the second example is the same as that of the first example except that the source line contact part SLC and the bit line contact part BLC have different shapes.

In the second example, a fringe is provided to each of the source line contact part SLC and the bit line contact part BLC of the active area AA such that the source line and the bit line come into easily contact with the active area AA.

Consequently, even if there occurs deviation in matching between the source line contact part SLC or the bit line contact part BLC and the contact holes, loose connection between the source line or the bit line and the active area AA is hard to occur.

### C-3 Third Example

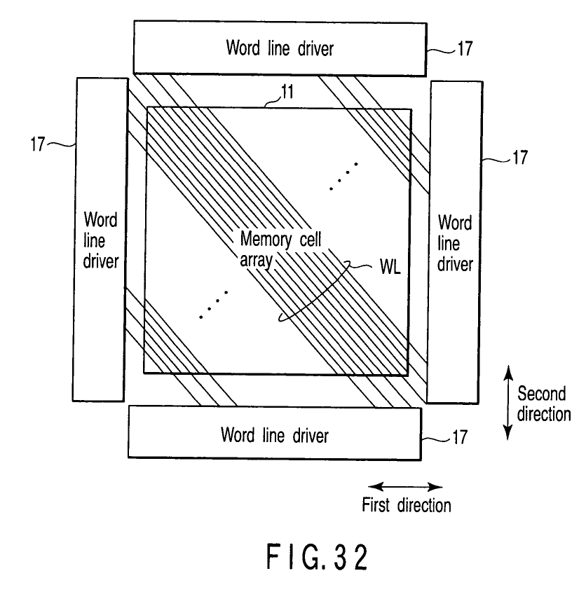

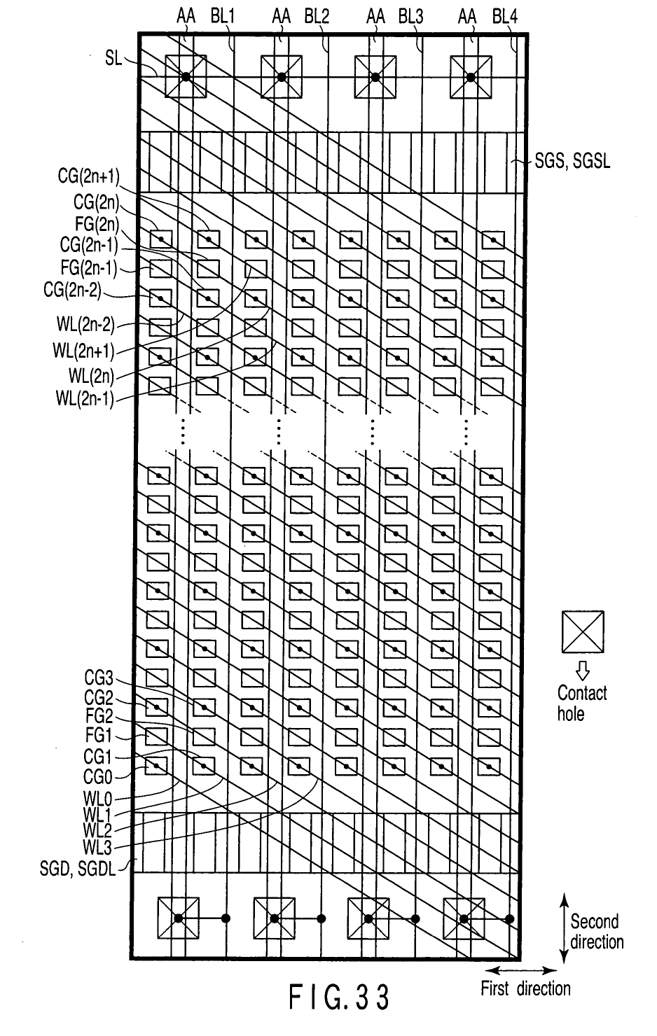

FIGS. 32 and 33 show a third example of the layout of the cell unit.

The third example is configured in such a manner that the layout of the word line, the select gate line, the source line and the bit line is further added to the layout of the first example.

The layout of the cell unit is the same as that of the first example.

The control gate electrodes CG0, CG1, . . . , CG(2n+1) arranged at both side surfaces of the active area AA are respectively connected to the word lines WL0, WL1, . . . , WL(2n+1) independently.

Here, assuming that the direction orthogonal to the longitudinal direction of the active area AA is defined as a first direction and the longitudinal direction of the active area AA is defined as a second direction, the word lines WL0, WL1, . . . , WL(2n+1) extend in a third direction between the first and the second directions. That is, the word lines WL0, WL1, . . . , WL(2n+1) are arranged obliquely to the active area AA.

As a result, the word line drivers 17 can be arranged on all sides of the memory cell array 11 when the whole shape of the memory cell array 11 is taken to be, for example, a four-sided figure as shown in FIG. 32.

The select gate electrodes SGS, SGD are connected to the select gate lines SGSL, SGDL. Here, the select gate lines SGSL, SGDL extend in a direction different from the direction in which the word lines WL0, WL1, . . . , WL(2n+1) extend, for example, extend in the first direction.

The select gate lines SGSL, SGDL may be connected to the select gate electrodes SGS, SGD via the contact hole, or may be directly brought into contact with the select gate electrodes SGS, SGD.

As for the word lines WL0, WL1, . . . , WL(2n+1) and the select gate lines SGSL, SGDL, it is possible to adopt a low resistance wiring structure such as a silicide structure or a metal structure.

The source line SL is connected on the source line contact part SLC via the contact hole. The source line SL extends in the first direction. The bit lines BL1, BL2, BL3, BL4, . . . are connected on the bit line contact part BLC via the contact holes. The bit lines BL1, BL2, BL3, BL4, . . . extend in the second direction.

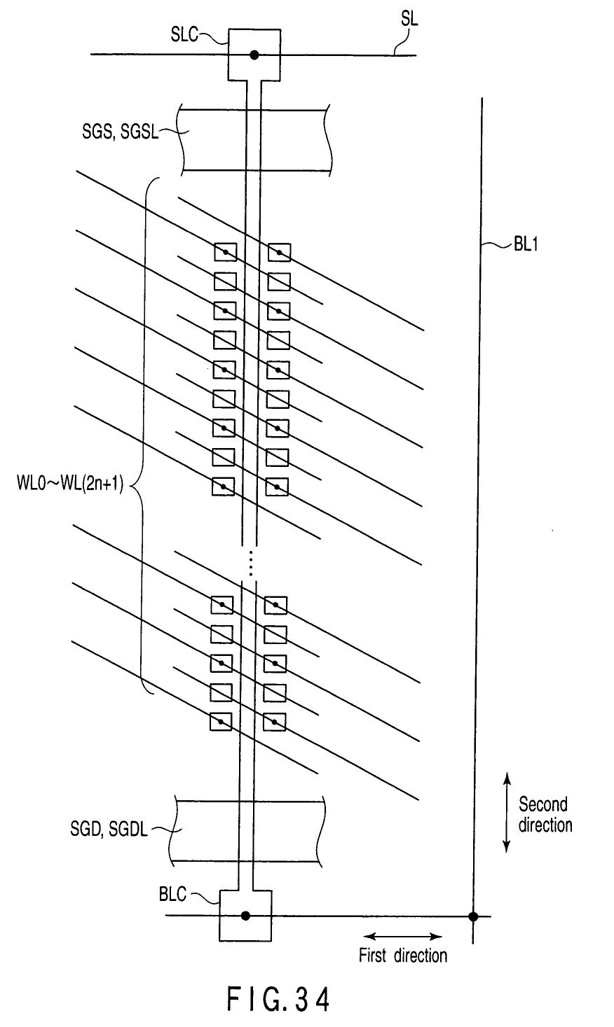

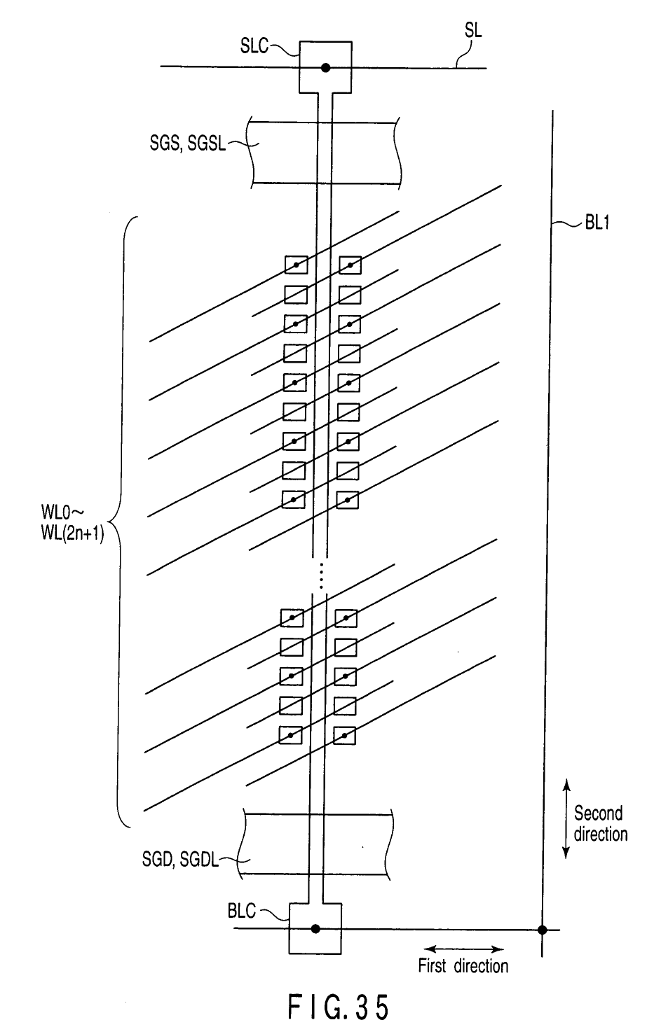

In the layout of the present embodiment, the word lines WL0, WL1, . . . , WL(2n+1) extend in a so-called oblique direction being neither the first nor the second direction. The layout of the word lines WL0, WL1, . . . , WL(2n+1) may be leftward up as shown in FIG. 34, or may be rightward up as shown in FIG. 35, for example.

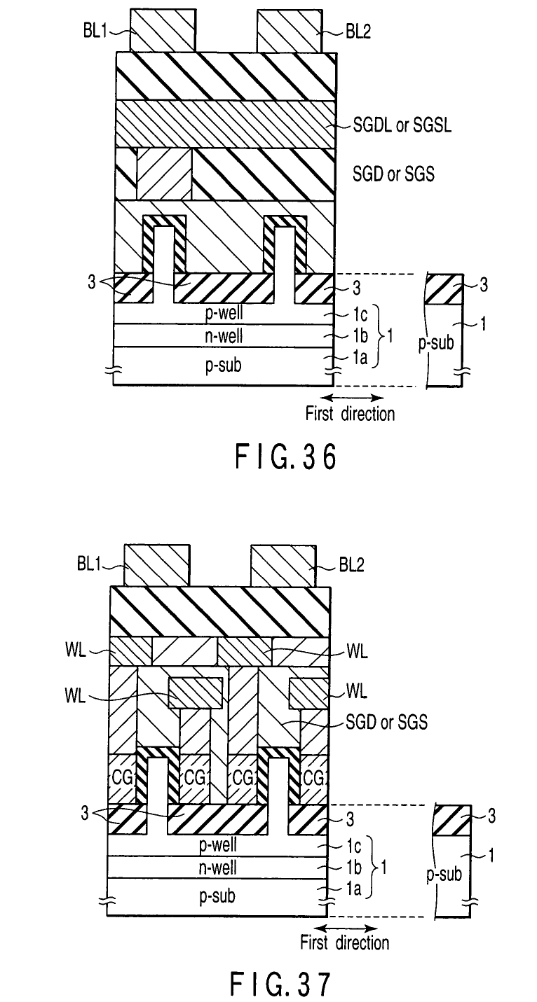

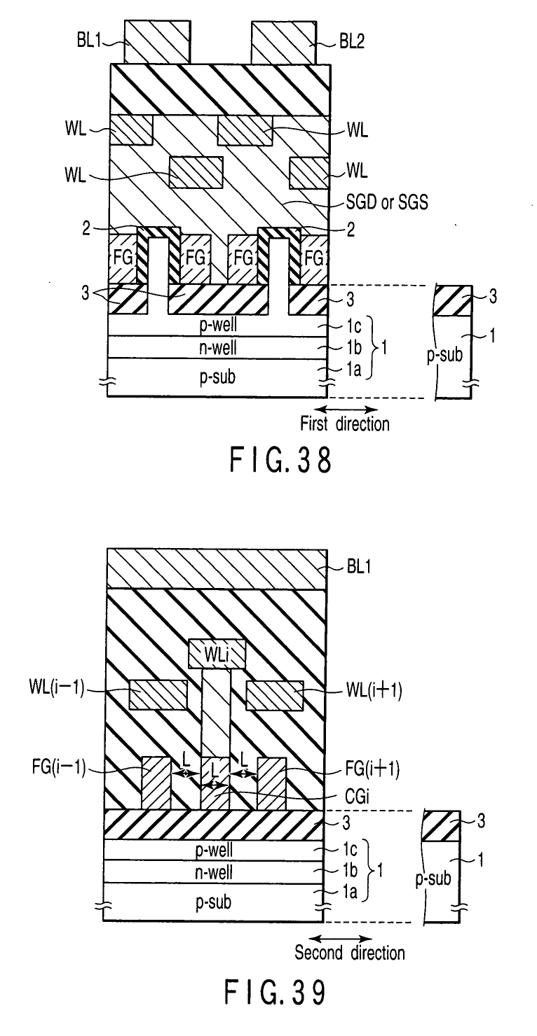

FIGS. 36 to 39 show an example of the device structure in the case where the layout of FIG. 33 is three-dimensionally formed.

A semiconductor substrate 1a is a p-type semiconductor substrate, and a double well region composed of an n-type well region 1b and a p-type well region 1c is formed in the surface region of the semiconductor substrate 1a. At a lower part of the fin-shaped active area AA, an element isolation insulating layer 3 with a shallow trench isolation (STI) structure is formed.

Of course, it is acceptable that the double well region is omitted and the fin-shaped active area AA is formed in the p-type semiconductor substrate 1.

Here, since the respective NAND strings are formed at both side surfaces of the active area AA in the multi-level type, density of the word line WL increases in two times compared with the 2-level type.

In this case, assume that all the word lines WL are formed in the same wiring layer. Provided the width of the floating gates FG1, FG2, . . . , FG(2n) and the control gate electrodes CG0, CG1, . . . , CG(2n+1) in the second direction are L, and a space between the both is L, the width of the word lines WL is also made L.

Accordingly, arranged on the different wiring layers are the word line WL connected to the NAND string arranged at one of two side surfaces of the active area AA and the word line connected to the NAND string arranged at the other. In such a way as above, the width of the word line WL can be enlarged up to the maximum value of degree of 2L.

Therefore, even if the Fin-type memory cell is miniaturized, it is possible to realize high-speed memory operation without increasing remarkably a contact resistance and a wiring resistance.

### D. Basic Operation

There will be described the basic operation of the multi-level Fin-NAND type flash memory according to the embodiment of the invention.

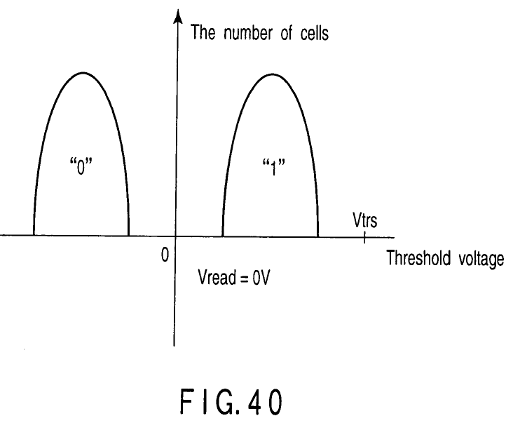

Here, for ease of explanation, it is provided that 2-level data “0”, “1” are stored in one Fin-type memory cell, and further, as shown in FIG. 40, a threshold voltage of the Fin-type memory cell for storing “0”-data is less than 0 V, while a threshold voltage of the Fin-type memory cell for storing “1”-data exceeds 0 V.

In FIG. 40, the relation between “0” and “1” becomes inverse to the case of the 2-level already described (FIG. 24). This suggests that both “0” and “1” can be set to either erase or write.

### D-1 Write Operation

First, assume that an initial state of the Fin-type memory cell, that is, an erase state is “0”. In this case, when observing, for example, two Fin-type memory cell MCi, MC(i+1) opposite to each other while sandwiching the active area AA therebetween, the data value is “00”.

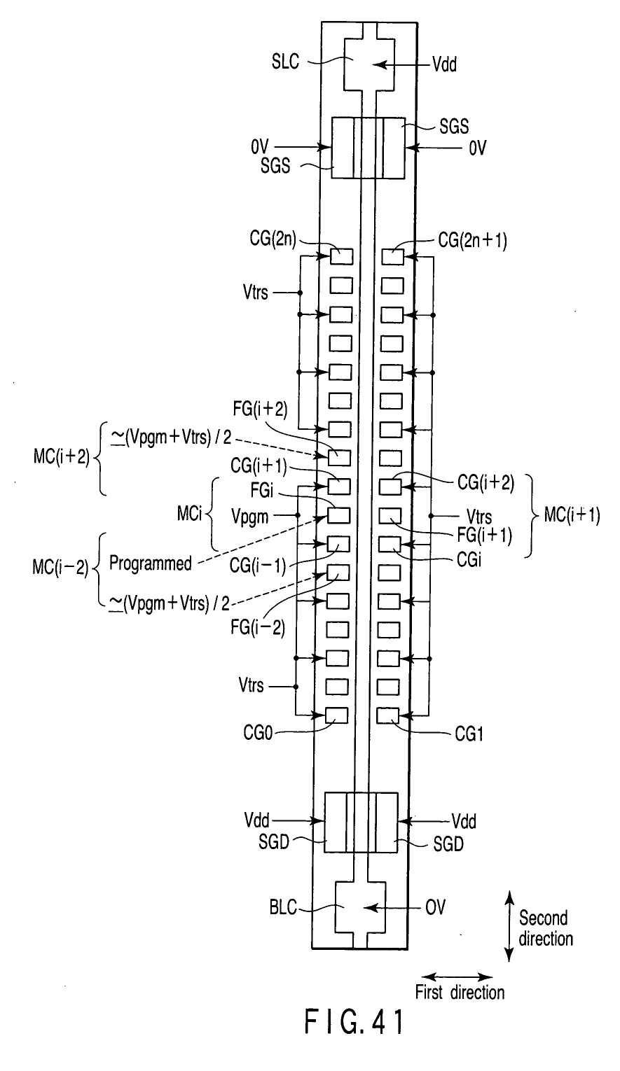

FIG. 41 shows a potential relation inside the cell unit in the case of writing “1” on the Fin-type memory cell MCi.

When executing the data writing to the Fin-type memory cell MCi, control gate electrodes CG(i−1), CG(i+1) existing on both sides of the floating gate FGi are set to a write potential Vpgm. At this time, the floating gate FGi following the potential of the control gate electrodes CG(i−1), CG(i+1) comes to a value near the write potential Vpgm.

A transfer potential Vtrs for turning the Fin-type memory cell on is applied to all the remaining control gate electrodes CG0, CG1, . . . , CG(i−2), CG1, CG(i+2), . . . CG(2n+1) except for the control gate electrodes CG(i−1), CG(i+1), respectively.

A grounding potential (0 V) for turning the select gate transistor off is applied to the select gate electrode SGS of the source side select gate transistor.

At this time, Vdd is applied to the source line contact part SLC and the select gate electrode SGD.

Then, write data is transferred to the cell unit via the bit line contact part BLC from the bit line.

Since write data is “1”, the bit line comes to, for example, a grounding potential of 0 V, and the grounding potential of 0 V is transferred to a channel of the Fin-type memory cell MCi. That is, electric charge (electron) is injected to the floating gate FGi of the Fin-type memory cell MCi, and then, the threshold voltage rises, so that “1”-data is written in the Fin-type memory cell MCi.

Therefore, when observing the two Fin-type memory cells MCi, MC(i+1), the data value comes to “10”.

Here, at the time of the write operation, the potentials of the floating gates FG(i−2), FG(i+2) of the non-selected Fin-type memory cells MC(i−2), MC(i+2) adjacent to the selected Fin-type memory cell MCi each come to values near (Vpgm+Vtrs)/2.

Therefore, conditions of the write potential Vpgm, the transfer potential Vtrs, the thickness of the tunnel insulating film and the like are set in order that error writing to the non-selected Fin-type memory cells MC(i−2), MC(i+2) does not occur and that data writing due to the intermediate potential (Vpgm+Vtrs)/2 does not occur.

Since the method of setting conditions is the same as the write operation of FIG. 25, the description thereof is omitted here.

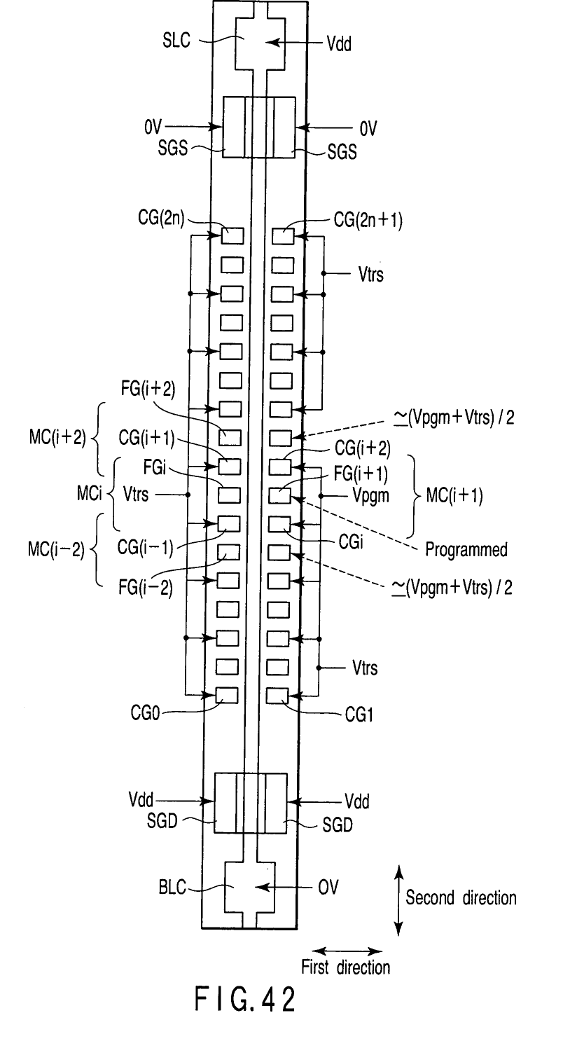

FIG. 42 shows a potential relation inside the cell unit in the case of writing “1” on the Fin-type memory cell MC(i+1).

When executing the data writing to the Fin-type memory cell MC(i+1), control gate electrodes CG1, CG(i+2) existing on both sides of the floating gate FG(i+1) are set to a write potential Vpgm. At this time, the floating gate FG(i+1) following the potential of the control gate electrodes CG1, CG(i+2) comes to a value near the write potential Vpgm.

A transfer potential Vtrs for turning the Fin-type memory cell on is applied to all the remaining control gate electrodes CG0, CG1, . . . , CG(i−1), CG(i+1), CG(i+3), . . . CG(2n+1) except for the control gate electrodes CG1, CG(i+2), respectively.

A grounding potential (0 V) for turning the select gate transistor off is applied to the select gate electrode SGS of the source side select gate transistor.

Vdd is applied to the select gate electrodes SGS, SGD, respectively, and the bit line contact part BLC is grounded.

Then, write data “1” is transferred to the cell unit via the bit line contact part BLC from the bit line.

That is, since the bit line comes to the grounding potential of 0 V, the grounding potential of 0 V is transferred to a channel of the Fin-type memory cell MC(i+1). As a result, electric charge (electron) is injected to the floating gate FG(i+1) of the Fin-type memory cell MC(i+1), and then, the threshold voltage rises, so that “1”-data is written in the Fin-type memory cell MC(i+1).

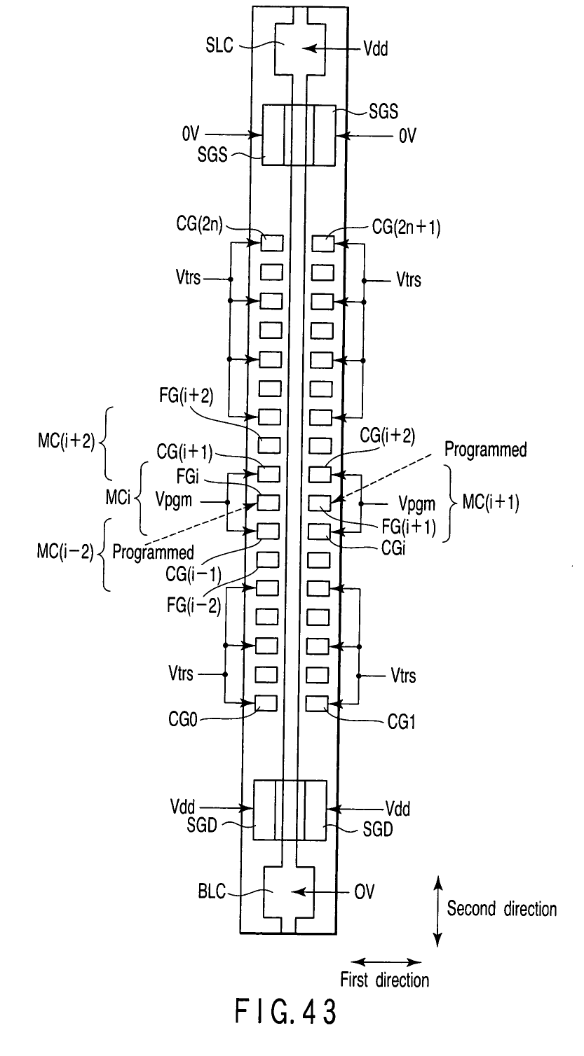

Accordingly, when observing the two Fin-type memory cells MCi, MC(i+1), the data value comes to FIG. 43 shows a potential relation inside the cell unit in the case where “1” is written in the two Fin-type memory cells MCi, MC(i+1) simultaneously.

When executing the data writing to the Fin-type memory cells MCi, MC(i+1) simultaneously, the control gate electrodes CG(i−1), CG1, CG(i+1), CG(i+2) existing on both sides of the floating gates FGi, FG(i+1) are set to the write potential Vpgm. At this time, the floating gates FGi, FG(i+1) following the potential of the control gate electrodes CG(i−1), CG1, CG(i+1), CG(i+2) comes to a value near the write potential Vpgm.

A transfer potential Vtrs for turning the Fin-type memory cell on is applied to all the remaining control gate electrodes CG0, CG1, . . . , CG(i−2), CG(i+3), . . . , CG(2n+1) except for the control gate electrodes CG(i−1), CG1, CG(i+1), CG(i+2), respectively.

Vdd is applied to the source line contact part SLC and the select gate electrode SGD, respectively, and the bit line contact part BLC is grounded.

The grounding potential (0 V) for turning the select gate transistor off is applied to the select gate electrode SGS of the source side select gate transistor.

That is, since the bit line comes to the grounding potential of 0 V, the grounding potential of 0 V is transferred to a channel of the Fin-type memory cells MCi, MC(i+1). As a result, electric charge (electron) is simultaneously injected to the floating gates FGi, FG(i+1) of the Fin-type memory cells MCi, MC(i+1), and then, the threshold voltage rises, so that “1”-data is written in the Fin-type memory cells MCi, MC(i+1).

Therefore, when observing the two Fin-type memory cells MCi, MC(i+1), the data value comes to “11”.

Thus, as for the data writing to the multi-level Fin-NAND type flash memory, the 2-bit data “00”, “10”, “01”“11”, “11” can be written to the FIN-type memory cell by one time of the write operation. As a consequence, the high-speed write operation can be achieved.

Of course, like an ordinary multi-level memory, when writing, for example, “11”, there may be adopted a 2-stage procedure such that “10” or “01” is input with the first write operation, and “11” is written with the second write operation so as to come to “11”.

### D-2 Read Operation

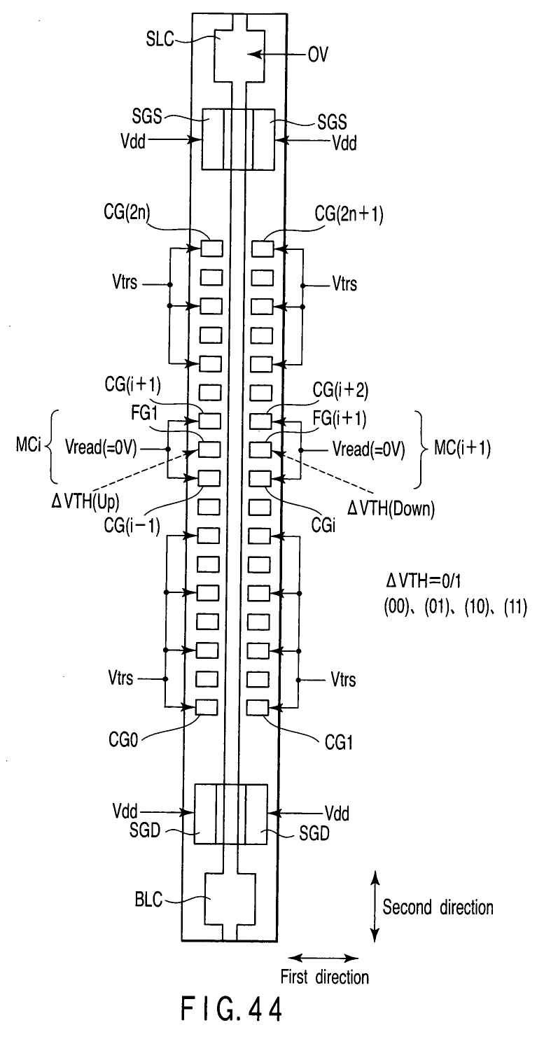

FIG. 44 shows a potential relation inside the cell unit at the time of the read operation.

When reading 2-bit data from the Fin-type memory cells MCi, MC(i+1) the control gate electrodes CG(i−1), CG1, CG(i+1), CG(i+2) existing on both sides of the floating gate FGi, FG(i+1) are set to the read potential Vread.

In the present embodiment, it is presupposed that the data value of the Fin-type memory cell shows the threshold distribution of FIG. 40. Therefore, the read potential Vread comes to 0 V. When the threshold distribution is changed, the value of the read potential Vread is changed according to its change.

In this case, as apparent from the threshold distribution of FIG. 40, the selected Fin-type memory cells MCi, MC(i+1) are turned on/off in accordance with the data value stored therein.

A transfer potential Vtrs for turning the Fin-type memory cell on is applied to all the remaining control gate electrodes CG0, CG1, . . . , CG(i−2), CG(i+3), . . . , CG(2n+1) except for the control gate electrodes CG(i−1), CG1, CG(i+1), CG(i+2), respectively.

Vdd is applied to the select gate electrodes SGS, SGD, respectively, and the source line contact part SLC is grounded.

Here, when the data stored in the Fin-type memory cells MCi, MC(i+1) is “00”, the value of the read current becomes largest, while when the data is “11”, the value of the read current becomes smallest. For this reason, in the case where 2-bit data come to these values “00”, “11”, the value of the read data is determined with 1 time of read operation.

On the contrary, in the case where the data stored in the Fin-type memory cells MCi, MC(i+1) are “10”, “01”, the value of the read current becomes the same. Therefore, in the case where the 2-bit data are the values “10”, “01”, the value of the read data is determined with 2 times of read operation.

That is, in the case where, with the first read operation, the data stored in the Fin-type memory cells MCi, MC(i+1) is first determined as “10” or “01”, the data reading is executed to only either one of the Fin-type memory cells MCi, MC(i+1) by the second read operation.

For example, in the case where the second read operation is performed to the Fin-type memory cell MCi, so that the data value of the Fin-type memory cell MCi is determined as “0”, the remaining data value of the Fin-type memory cell MC(i+1) is automatically determined as “1”. Further, in the case where, with the second read operation, the data stored in the Fin-type memory cells MCi is determined as “1”, the remaining data value of the Fin-type memory cell MC(i+1) is automatically determined as “0”.

Note that, in the example described above, the number of times of the read operation changes in accordance with the data value stored in the Fin-type memory cells MCi, MC(i+1).

Instead of this, it is also possible to always read the 2-bit data from the Fin-type memory cells MCi, MC(i+1) due to two times of the read operation. That is, data of one of the Fin-type memory cells MCi, MC(i+1) can be read by the first read operation, and data of the other of the Fin-type memory cells MCi, MC(i+1) can be read by the second read operation.

Further, the above embodiment has described the case in which the 2-bit data is read from the Fin-type memory cells MCi, MC(i+1). However, of course, it is also possible to read only data of one of Fin-type memory cells MCi, MC(i+1) independently.

### D-3 Erase Operation

The erase operation of the multi-level type is, for example, performed to a plurality of Fin-type memory cells with the erase operation lumped. Since the potential relation in this case is substantially the same as that of the erase operation shown in FIG. 27, the description is omitted here.

### E. Others

The above description has been made as for the multi-level NAND type flash memory. However, the Fin-type memory cell with the basic structure shown in FIGS. 28 and 29 can be applied to a memory cell array structure except for the NAND type, that is, applied to a memory cell array structure such as NOR type, 2-Tr type, or 3-Tr NAND type.

### 3. Application Example

It is the most preferable for the Fin-type memory cell according to the embodiment of the invention to be mixed-mounted inside a system LSI having a logic circuit composed of Fin-FET.

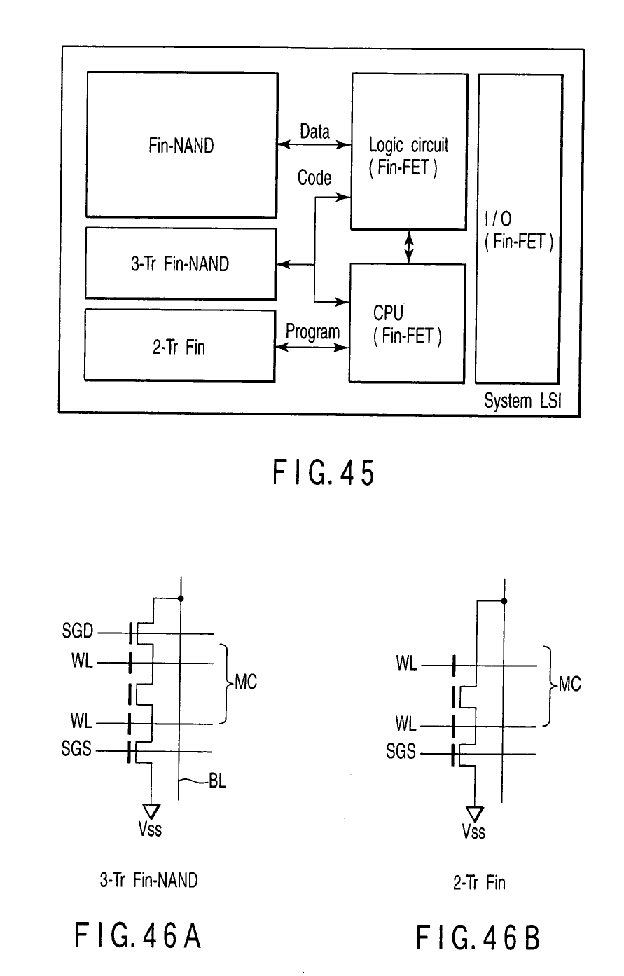

FIG. 45 shows one example of the system LSI.

Inside the system LSI (chip), there are mounted a central processing unit (CPU), a logic circuit, a Fin-NAND type flash memory (Fin-NAND), a 3-Tr Fin-NAND type flash memory (3-Tr Fin-NAND), a 2-Tr Fin type flash memory (2-Tr Fin) and an input/output circuit (I/O).

The CPU, the logic circuit and the I/O are respectively constituted by Fin-FET. Further, the Fin-NAND, the 3-Tr Fin-NAND and the 2-Tr Fin each are composed of the Fin-type memory cell according to the embodiment of the invention.

Here, the configuration of the Fin-NAND has been already described in detail. However, in addition thereto, for example, when the Fin-type memory cell according to the embodiment of the invention is applied to the 3-Tr Fin-NAND, the circuit configuration comes to one shown in FIG. 46A, or when the Fin-type memory cell is applied to the 2-Tr Fin, the circuit configuration comes to one shown in FIG. 46B.

### 4. Others

According to the embodiments of the invention, there can be realized the Fin-type memory cell having a suitable structure for mixed-mounting with the logic circuit composed of the Fin-FET.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A fin type memory cell comprising:
a fin-shaped active area;
a floating gate arranged along a side surface in a longitudinal direction of the fin-shaped active area; and
two control gate electrodes arranged along a side surface of the longitudinal direction of the floating gate, and sandwiching the floating gate.

2. The fin type memory cell according to claim 1,
wherein, when programming a data to the floating gate, an electric charge is moved from the fin-shaped active area to the floating gate by supplying a write potential to the two control gate electrodes.

3. The fin type memory cell according to claim 1,
wherein, when reading a data stored in the floating gate, read data is determined based on a current flowing in the Fin-type memory cell while supplying a read potential to the two control gate electrodes.

4. The fin type memory cell according to claim 1,
wherein, when erasing data out of the floating gate, an electric charge is moved from the floating gate to the fin-shaped active area by supplying an erase potential to the fin-shaped active area and supplying a lower potential than the erase potential to the two control gate electrodes.

5. A fin type memory cell comprising:
a fin-shaped active area;
a first floating gate arranged along a first side surface in a longitudinal direction of the fin-shaped active area;
a second floating gate arranged along a second side surface different from the first side surface of the fin-shaped active area;
first and second control gate electrodes arranged along a side surface of the longitudinal direction of the first floating gate, and sandwiching the first floating gate; and
third and fourth control gate electrodes arranged along a side surface of the longitudinal direction of the second floating gate, and sandwiching the second floating gate.

6. The fin type memory cell according to claim 5,
wherein the first and second floating gates store the same data.

7. The fin type memory cell according to claim 5,
wherein the first and third control gate electrodes are connected to a first word line, while the second and fourth control gate electrodes are connected to a second word line different from the first word line.

8. The fin type memory cell according to claim 5,
wherein the first and second floating gates store different data.

9. The fin type memory cell according to claim 5,
wherein the first to fourth control gate electrodes are independently connected to the first to fourth word lines, respectively.

10. A Fin-NAND type flash memory comprising:
a fin-shaped active area;
floating gates and control gate electrodes which are alternately arranged along a side surface of the fin-shaped active area in its longitudinal direction; and
a Fin type memory cell composed of one of the floating gates and the two control gate electrodes arranged at positions mutually adjacent to the one electrode.

11. The Fin-NAND type flash memory according to claim 10,
wherein a NAND string is composed of the floating gates and the control gate electrodes in which the NAND string terminates at both ends with two of the control gate electrodes.

12. The Fin-NAND type flash memory according to claim 11,
wherein there are provided two select gate transistors arranged at both ends of the NAND string one by one each, and each select gate transistor has a diffusion layer to be formed inside the fin-shaped active area and select gate electrodes to be formed on the first and second side surfaces.

13. The Fin-NAND type flash memory according to claim 12,
wherein one of the two select gate transistors is connected to a source line, while the other is connected to a bit line, the bit line extending in a longitudinal direction of the fin-shaped active area and being connected to an upper surface of the fin-shaped active area.

14. The Fin-NAND type flash memory according to claim 10,
wherein, when programming a data to one floating gate selected among the floating gates, a write potential is applied to the two control gate electrodes mutually adjacent to the one selected electrode, while a transfer potential turning a Fin-type memory cell ON regardless of data stored therein, and being lower than the write potential, is applied to the other control gate electrodes.

15. The Fin-NAND type flash memory according to claim 14,
wherein the write potential and the transfer potential are set to a value by which a data writing is not generated on two floating gates adjacent in a longitudinal direction of the fin-shaped active area to the one selected floating gate.

16. The Fin-NAND type flash memory according to claim 10,
wherein, when reading a data stored in one floating gate selected among the floating gates, a read potential is applied to the two control gate electrodes mutually adjacent to the one selected electrode, while a transfer potential turning the Fin-type memory cell ON regardless of data stored therein, and being higher than the read potential, is applied to the other control gate electrodes.

17. The Fin-NAND type flash memory according to claim 10,
wherein, when erasing a data out of all the floating gates in a block, an erase potential is applied to the fin-shaped active area in the block, while a lower potential than the erase potential is applied to all the control gate electrodes in the block.

18. A Fin-NAND type flash memory comprising:
a fin-shaped active area;
first floating gates and first control gate electrodes which are alternately arranged along a first side surface of the fin-shaped active area in its longitudinal direction;
second floating gates and second control gate electrodes which are alternately arranged along a second side surface different from the first side surface of the fin-shaped active area in its longitudinal direction; and
a Fin-type memory cell composed of one of the first floating gates and the two first control gate electrodes arranged at positions mutually adjacent to the one first floating gate, and one of the second floating gates and the two second control gate electrodes arranged at positions mutually adjacent to the one second floating gate.

19. The Fin-NAND type flash memory according to claim 18,
wherein a NAND string is composed of the first and second floating gates and the first and second control gate electrodes in which the NAND string terminates at both ends with two of the first and second control gate electrodes.

20. The Fin-NAND type flash memory according to claim 19,
wherein the NAND string each has two select gate transistors arranged at its both ends one by one each, and each select gate transistor has a diffusion layer to be formed inside the fin-shaped active area and a select gate electrode to be formed on the first and second side surfaces.

21. The Fin-NAND type flash memory according to claim 20,
wherein one of the two select gate transistors is connected to a source line, while the other is connected to a bit line, the bit line extending in a longitudinal direction of the fin-shaped active area and being connected to an upper surface of the fin-shaped active area.

22. The Fin-NAND type flash memory according to claim 18,
wherein the first control gate electrodes and the second control gate electrodes are connected to common word lines.

23. A Fin-NAND type flash memory comprising:
a fin-shaped active area;
first floating gates and first control gate electrodes which are alternately arranged along a first side surface of the fin-shaped active area in its longitudinal direction;
second floating gates and second control gate electrodes which are alternately arranged along a second side surface different from the first side surface of the fin-shaped active area in its longitudinal direction;
a first Fin-type memory cell composed of one of the first floating gates and the two first control gate electrodes arranged at positions mutually adjacent to the one first floating gate; and
a second Fin-type memory cell composed of one of the second floating gates and the two second control gate electrodes arranged at positions mutually adjacent to the one second floating gate.

24. The Fin-NAND type flash memory according to claim 23,
wherein a first NAND string is composed of the first floating gates and the first control gate electrodes, and a second NAND string is composed of the second floating gates and the second control gate electrodes, each of the first and second NAND string terminating at one of the first and second control gate electrodes.

25. The Fin-NAND type flash memory according to claim 24,
wherein the first and second NAND strings each have two select gate transistors arranged at its both ends one by one each, and each select gate transistor has a diffusion layer to be formed inside the fin-shaped active area and a select gate electrode to be formed in such a way as to straddle the first and second side surfaces.

26. The Fin-NAND type flash memory according to claim 25,
wherein one of the two select gate transistors is connected to a source line, while the other is connected to a bit line, the bit line extending in a longitudinal direction of the fin-shaped active area and being connected to an upper surface of the fin-shaped active area.

27. The Fin-NAND type flash memory according to claim 23,
wherein the first control gate electrodes are connected to first word lines, and the second control gate electrodes are connected to second word lines different from the first word lines.

28. A semiconductor memory comprising:
a memory cell array composed of memory cells arranged in first and second directions orthogonal to each other in an array shape; and
a word line connected to a gate of the memory cells, and extending in a third direction between the first and the second directions,
wherein the memory cells connected in common to one of the word lines are arranged in the third direction.

29. The semiconductor memory according to claim 28, further comprising:
source lines connected to an end part at a source side of the memory cells, and extending in the first direction; and
bit lines connected to an end part at a drain side of the memory cells, and extending in the second direction.

30. The semiconductor memory according to claim 29,
wherein the memory cell arranged in the second direction among the memory cells constitutes a NAND string while being serially connected to each other, total two select gate transistors are connected to both ends of the NAND string one by one each, the source line is connected to a diffusion layer of the select gate transistor at a source side of the NAND string, the bit line being connected to a diffusion layer of the select gate transistor at a drain side of the NAND string, and a word line to be connected to a gate of the two select gate transistors extends in the third direction.

31. The semiconductor memory according to claim 30,
wherein the memory cells each are composed of a floating gate along one of the first and second side surfaces different from each other of a fin-shaped active area, and two control gate electrodes arranged at positions to sandwich the floating gate, along one of the first and second side surfaces.

32. The semiconductor memory according to claim 31,
wherein a word line to which a control gate electrode arranged at the first side surface of the fin-shaped active area is connected resides on a higher position than a word line to which a control gate electrode arranged at the second side surface of the fin-shaped active area is connected.

33. The semiconductor memory according to claim 28,
wherein each of word line drivers which drive the word lines resides on all sides of the memory cell array.
